(19) United States
(12) Patent Application Publication
(10) Pub. No.: US 2026/0153805 A1
(43) Pub. Date: Jun. 4, 2026

(54) PHOTOSENSITIVE RESIN COMPOSITION, INSULATING FILM, AND DISPLAY DEVICE COMPRISING SAME

(71) Applicant: DONGJIN SEMICHEM CO., LTD., Incheon (KR)

(72) Inventors: Ah Rum PARK, Hwaseong-si (KR); Hyoc Min YOUN, Hwaseong-si (KR); Tai Hoon YEO, Hwaseong-si (KR); Dong Myung KIM, Hwaseong-si (KR); Gyu Hyun HWANG, Hwaseong-si (KR); Gyu Tae PARK, Hwaseong-si (KR); Yoo Dong CHANG, Hwaseong-si (KR); Jae Won JEONG, Hwaseong-si (KR); Hyeong Jin LEE, Hwaseong-si (KR)

(21) Appl. No.: 19/460,356

(22) Filed: Jan. 27, 2026

Related U.S. Application Data
(63) Continuation of application No. PCT/KR2024/011111, filed on Jul. 30, 2024.

(30) Foreign Application Priority Data
Jul. 31, 2023 (KR) 10-2023-0100096
Jul. 29, 2024 (KR) 10-2024-0100558

(51) Int. Cl. G03F 7/039; C08F 234/02; C08K 5/053; C08K 5/08; C08K 5/18; C08K 5/32; C08K 5/3445; G03F 7/004

(52) U.S. Cl. CPC G03F 7/0392; C08F 234/02; C08K 5/053; C08K 5/08; C08K 5/18; C08K 5/32; C08K 5/3445; G03F 7/0045

(57) ABSTRACT

A photosensitive resin composition having a coloring function is provided. According to one aspect, the provided photosensitive resin composition includes an alkali-soluble resin and a photoactive compound, wherein the alkali-soluble resin and/or the photoactive compound has an absorption maximum of a wavelength of 400 to 550 nm on the basis of UV-vis spectroscopy.

### CROSS-REFERENCES TO RELATED APPLICATIONS

This application is a Continuation of International Application No. PCT/KR2024/011111 filed on Jul. 30, 2024, which claims priority from Korean Patent Application No. 10-2023-0100096, filed on Jul. 31, 2023; and Korean Patent Application No. 10-2024-0100558, filed on Jul. 29, 2024. The aforementioned applications are incorporated herein by reference in their entireties.

### BACKGROUND OF THE INVENTION

The present disclosure relates to a photosensitive resin composition, and more specifically, to a photosensitive resin composition, an insulating film, and a display device including the same.

Photosensitive resin compositions are representative functional polymer materials that have been put to practical use in the production of various precision electronic products, and are currently being used significantly in advanced technology industries, particularly in the production of semiconductors and displays. Generally, the photosensitive resin composition refers to a composition which, upon exposure to light, undergoes a chemical change in its molecular structure within a short period of time, which results in changes in physical properties such as solubility in a specific solvent, coloration, and curing.

The use of the photosensitive resin compositions enables fine precision processing, can greatly reduce energy and raw materials compared to those in thermal reaction processes, and allows work to be performed quickly and accurately in a small installation space. Thus, the photosensitive resin compositions are widely used in various precision electronic industries such as advanced printing field, semiconductor production, display production, and photocurable surface coating materials. These photosensitive resin compositions can be broadly classified into a negative type and a positive type. The negative-type photosensitive resin composition is a type in which a light-irradiated portion becomes insoluble in a developer, and the positive-type photosensitive resin composition is a type in which a light-irradiated portion becomes soluble in a developer. Recently, as electronic devices have become more highly integrated and been formed with a fine pattern, positive photosensitive resin compositions capable of minimizing defect rates and increasing processing efficiency and resolution have been mainly used.

### SUMMARY OF THE INVENTION

### Technical Problem

An object of the present disclosure is to provide a photosensitive resin composition capable of lowering the transmittance of a patterned film.

Another object of the present disclosure is to provide a photosensitive resin composition having a suitable level of sensitivity and excellent film retention rate, adhesion of a cured film to a substrate, chemical resistance, heat resistance, low hygroscopicity, and device reliability.

Still another object of the present disclosure is to provide a photosensitive resin composition having a coloring function.

Yet another object of the present disclosure is to provide an insulating film including a cured product of the photosensitive resin composition.

Still yet another object of the present disclosure is to provide a display device including the insulating film.

The objects of the present disclosure are not limited to the above-mentioned objects, and other objects and advantages of the present disclosure not mentioned may be understood through the following description and will be more clearly understood through embodiments of the present disclosure. In addition, it will be readily apparent that the objects and advantages of the present disclosure may be realized by the means and combinations thereof set forth in the claims.

### Technical Solution

[1] According to one aspect of the present disclosure for achieving the above objects, there is provided a photosensitive resin composition comprising: an alkali-soluble resin; and a photoactive compound, wherein at least any one of the alkali-soluble resin and the photoactive compound has an absorption maximum (inflection point) at a wavelength of 400 to 550 nm as measured by UV-Vis spectroscopy.

[2] In [1] above, at least any one of the alkali-soluble resin and the photoactive compound may comprise any one or more of structures represented by Formulas 1, 2-1 to 2-3, and 3 to 7 below. Preferably, at least any one of the alkali-soluble resin and the photoactive compound may comprise a combination of structures of Formulas 1 and 2-1 below, a combination of structures of Formulas 1 and 2-2 below, or a combination of structures of Formulas 2-2 and 2-3 below. According to some embodiments of the present disclosure, at least any one of the alkali-soluble resin and the photoactive compound may comprise a combination of structures of Formulas 1 and 2-1 below, a combination of structures of Formulas 1 and 2-2 below, or a combination of structures of Formulas 2-2 and 2-3 below, thereby realizing a higher film retention rate.

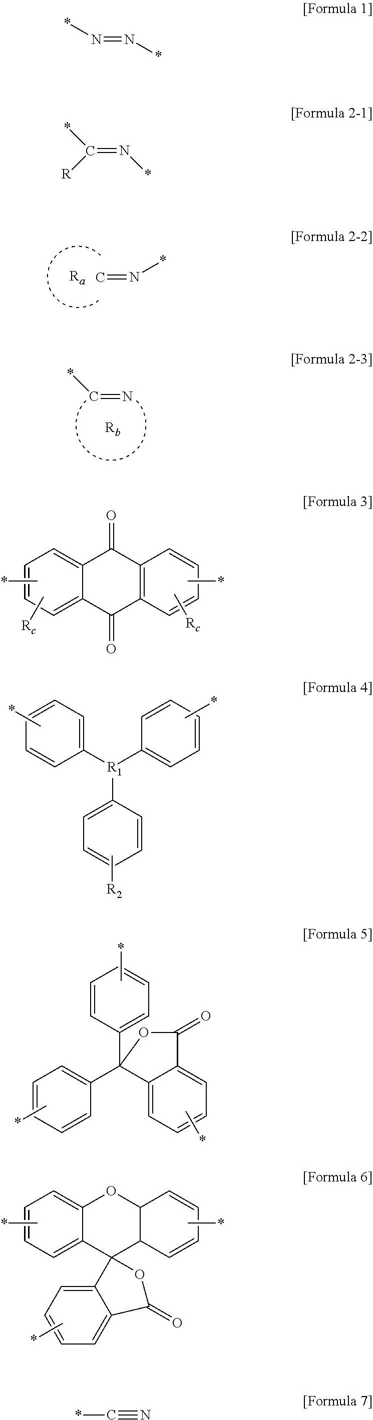

R in Formula 2-1 above is hydrogen or a substituted or unsubstituted organic group; Rₐ and R_{b} in Formulas 2-2 and 2-3 above are each independently a substituted or unsubstituted pentagonal ring or a substituted or unsubstituted hexagonal ring; R_{c} in Formula 3 above are each independently a hydrogen atom or a substituted or unsubstituted hydrocarbon group having one or more carbon atoms; and R₁ in Formula 4 above comprises a trivalent organic group or a nitrogen atom, and R₂ each independently comprise a hydrogen atom, a hydroxyl group, a sulfonic acid ester group, or a substituted or unsubstituted hydrocarbon group having one or more carbon atoms.

[3] In [1] or [2] above, the alkali-soluble resin may comprise a structure derived from any one of the compounds represented by Formulas 1a to 1j below.

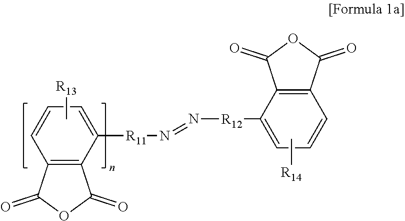

In Formula 1a above, R₁₁ and R₁₂ each independently comprise a direct bond, a hydrogen atom, or a divalent organic group, wherein, when any one of R₁₁ and R₁₂ is a hydrogen atom, the other is a direct bond or a divalent organic group; n is 0 or 1; and R₁₃ and R₁₄ are each independently a hydrogen atom, a hydroxyl group, a substituted or unsubstituted alkyl group having 1 or more carbon atoms, or a substituted or unsubstituted aryl group having 6 or more carbon atoms.

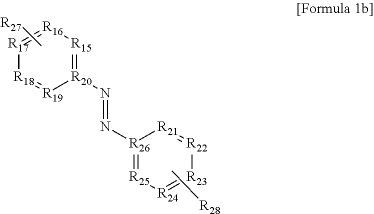

In Formula 1b above, R₁₅ to R₂₆ are each independently carbon or a heteroatom, R₂₇ and R₂₈ are each independently a mono- to penta-substituted substituent in the ring, wherein the substituents each independently comprise a hydrogen atom, a nitro group, a hydroxyl group, or an amine group, and at least any one of the substituents is an amine group.

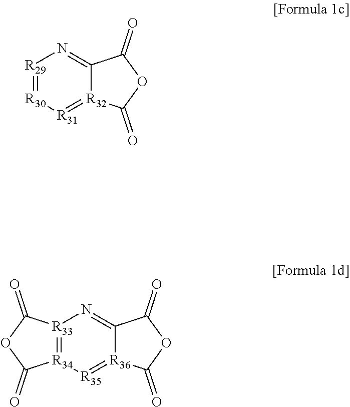

In Formulas 1c and 1d above, R₂₉ to R₃₆ are each independently carbon or a heteroatom.

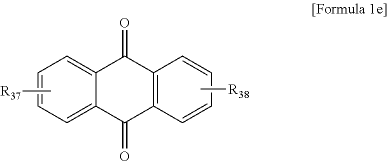

In Formula 1e above, R₃₇ and R₃₈ are each independently a mono- to tetra-substituted substituent, wherein the substituents are each independently a hydrogen atom, an amine group, or an acid anhydride group, and at least any one of the substituents is an amine group or an acid anhydride group, wherein the acid anhydride group is formed as substituents bond to each other when each of R₃₇ and R₃₈ is poly-substituted.

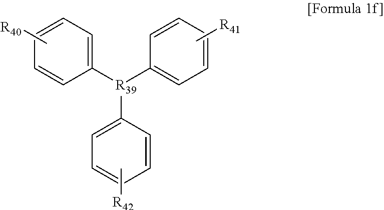

In Formula 1f above, R₃₉ is a trivalent organic group or a nitrogen atom, and R₄₀ to R₄₂ are each independently a mono- to penta-substituted substituent which is a hydrogen atom or an amine group, wherein at least any one of R₄₀ to R₄₂ is an amine group.

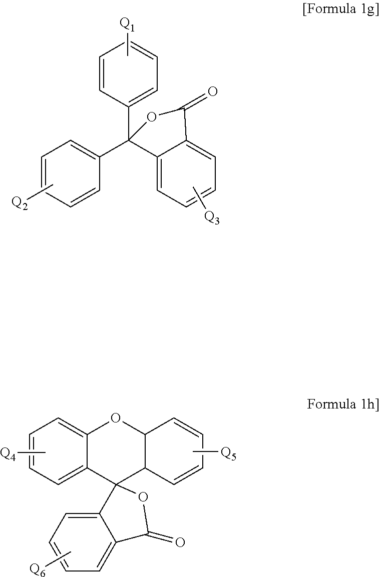

In Formulas 1g and 1h above, Q₁ to Q₆ are each independently a mono- or poly-substituted substituent which is a hydrogen atom, an amine group, or an acid anhydride group, wherein at least any one of Q₁ to Q₃ is an amine group or an acid anhydride group, wherein the acid anhydride group is formed as substituents bond to each other when any one or more of Q₁ to Q₃ are poly-substituted, and wherein at least any one of Q₄ to Q₆ is an amine group or an acid anhydride group, wherein the acid anhydride group is formed as substituents bond to each other when any one or more of Q₄ to Q₆ are poly-substituted.

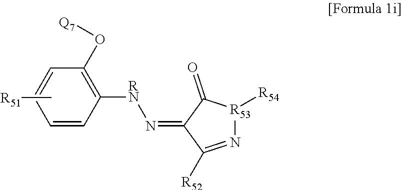

In Formula 1i above, Q₇ comprises a hydrogen atom, a substituted or unsubstituted alkyl group having 1 or more carbon atoms, a substituted or unsubstituted aryl group having 6 or more carbon atoms, an amine group, or an acid anhydride group, wherein Q₇ comprises at least one amine group or at least one acid anhydride group; R₅₁, R₅₂, and R₅₄ are each independently a hydrogen atom, a nitro group, a hydroxyl group, a substituted or unsubstituted alkyl group having one or more carbon atoms, or a substituted or unsubstituted aryl group having 6 or more carbon atoms; R₅₃ is a nitrogen atom; and R bonded to N is a hydrogen atom or a substituted or unsubstituted organic group. For example, when Q₇ is the substituted alkyl group or the substituted aryl group, it may comprise at least one amine group or at least one acid anhydride group.

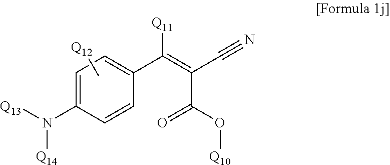

In Formula 1j above, Q₁₀ to Q₁₂ are each independently a hydrogen atom, a hydroxyl group, a substituted or unsubstituted alkyl group having one or more carbon atoms, or a substituted or unsubstituted aryl group having 6 or more carbon atoms, and Q₁₃ and Q₁₄ each independently comprise a hydrogen atom, at least one amine group, or at least one acid anhydride group.

[4] In any one of [1] to [3] above, the alkali-soluble resin may comprise any one selected from the group consisting of polyamic acid, polyamic ester, and polyimide.

[5] In [4] above, the degree of imidization of the polyimide may be 50% or more.

[6] In any one of [3] to [5] above, the alkali-soluble resin may comprise a structure derived from any one of the compounds represented by Formulas 1a to 1j in an amount of 5 mol % or more based on the total moles of the alkali-soluble resin.

[7] In any one of [1] to [6] above, the photoactive compound may comprise a sulfonic acid-esterified quinone diazide compound.

[8] In [7] above, the sulfonic acid-esterified quinone diazide compound may comprise a phenolic compound as a ballast.

[9] In [8] above, the phenolic compound may comprise any one or more of compounds represented by Formulas 2a to 2j below.

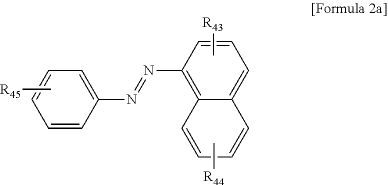

In Formula 2a above, R₄₃ to R₄₅ are each independently a mono- or poly-substituted substituent, wherein the substituents are each independently a hydrogen atom, a nitro group, or a hydroxyl group, and at least any one of the substituents is a hydroxyl group.

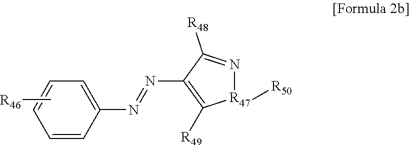

In Formula 2b above, R₄₆ is a mono- to penta-substituted substituent which are each independently a hydrogen atom, a nitro group, or a hydroxyl group, wherein at least any one of R₄₆ comprises a hydroxyl group; R₄₇ is a nitrogen atom; and R₄₈ to R₅₀ are each independently a hydrogen atom, a hydroxyl group, a nitro group, a substituted or unsubstituted alkyl group having one or more carbon atoms, or a substituted or unsubstituted aryl group having 6 or more carbon atoms.

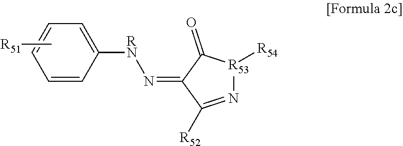

In Formula 2c above, R₅₁ is a mono- to penta-substituted substituent which are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of R₅₁ is a hydroxyl group; R₅₂ and R₅₄ are each independently a hydrogen atom, a nitro group, a hydroxyl group, a substituted or unsubstituted alkyl group having one or more carbon atoms, or a substituted or unsubstituted aryl group having 6 or more carbon atoms; R₅₃ is a nitrogen atom; and R bonded to N is a hydrogen atom or a substituted or unsubstituted organic group.

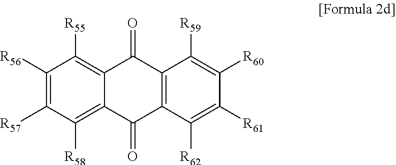

In Formula 2d above, R₅₅ to R₆₂ are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of R₅₅ to R₆₂ is a hydroxyl group.

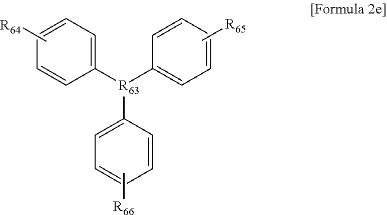

In Formula 2e above, R₆₃ is a trivalent organic group or a nitrogen atom; and R₆₄ to R₆₆ are each independently a mono- to penta-substituted substituent which is a hydrogen atom, a nitro group, a hydroxyl group, a substituted or unsubstituted alkyl group having one or more carbon atoms, or a substituted or unsubstituted aryl group having 6 or more carbon atoms, wherein at least any one of R₆₄ to R₆₆ is a hydroxyl group.

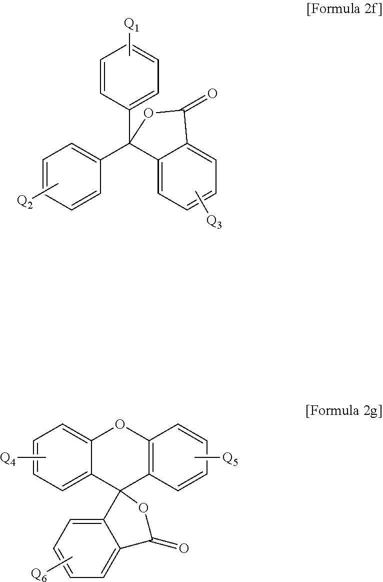

In Formulas 2f and 2g above, Q₁ to Q₆ are each independently a mono- or poly-substituted substituent, and are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of Q₁ to Q₃ is a hydroxyl group, and at least any one of Q₄ and Q₆ is a hydroxyl group. In some examples, Q₁ to Q₆ may each independently be a mono-substituted, di-substituted, tri-substituted, or tetra-substituted substituent.

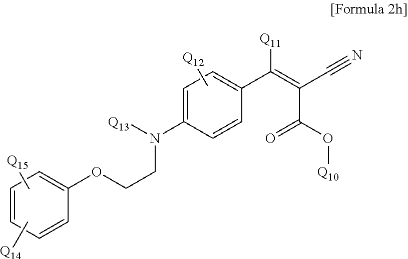

In Formula 2h above, Q₁₀ to Q₁₂ are each independently a hydrogen atom, a nitro group, a hydroxyl group, a substituted or unsubstituted alkyl group having one or more carbon atoms, or a substituted or unsubstituted aryl group having 6 or more carbon atoms; Q₁₃ is a hydrogen atom, a substituted or unsubstituted alkyl group having one or more carbon atoms, or a substituted or unsubstituted aryl group having 6 or more carbon atoms; and Q₁₄ and Q₁₅ are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of Q₁₄ and Q₁₅ is a hydroxyl group.

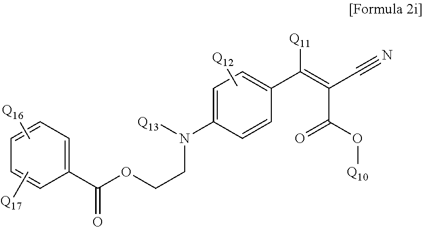

In Formula 2i above, Q₁₀ to Q₁₂ are each independently a hydrogen atom, a nitro group, a hydroxyl group, a substituted or unsubstituted alkyl group having one or more carbon atoms, or a substituted or unsubstituted aryl group having 6 or more carbon atoms; Q₁₃ is a hydrogen atom, a substituted or unsubstituted alkyl group having one or more carbon atoms, or a substituted or unsubstituted aryl group having 6 or more carbon atoms; and Q₁₆ and Q₁₇ are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of Q₁₆ and Q₁₇ is a hydroxyl group.

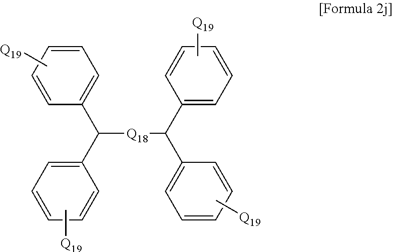

In Formula 2j above, Q₁₈ is a divalent linking group comprising at least one aromatic ring, and Q₁₉ are each independently a mono- to penta-substituent in the benzene ring, wherein at least any one of the mono- to penta-substituted substituents is a hydroxyl group. For example, Q₁₈ may be a phenylene group or a naphthalene group, and all hydroxyl groups in Q₁₉ may be substituted at para-positions relative to all the four benzene rings, and the remaining substituents may all be hydrogen atoms.

[10] In any one of [7] to [9] above, the content of the sulfonic acid-esterified quinone diazide compound may be 5 to 40 parts by weight based on 100 parts by weight of the alkali-soluble resin.

[11] In any one of [1] to [10] above, the photosensitive resin composition may further comprise a solvent.

[12] In any one of [1] to [11] above, the photosensitive resin composition may further comprise at least any one of a crosslinking agent, a thermal acid generator, and a UV absorber.

[13] In any one of [7] to [12] above, the degree of sulfonic acid esterification of the sulfonic acid-esterified quinone diazide compound may be 1.0 to 3.3% as measured according to an ultra-performance liquid chromatography (UPLC) analysis method.

[14] According to another aspect of the present disclosure, there is provided an insulating film comprising a cured product of the photosensitive resin composition according to any one of [1] to [13].

[15] According to still another aspect of the present disclosure, there is provided a display device comprising the insulating film according to [14]. Preferably, the display device may be an OLED device.

The above-described solution to the problem does not enumerate all the features of the present disclosure. Various features of the present disclosure and the resulting advantages and effects may be understood in more detail by referring to the following specific embodiments.

According to one aspect of the present disclosure, it is possible to easily impart coloring properties without separately adding a colored additive.

According to another aspect of the present disclosure, while imparting the above-described coloring properties, it is possible to maintain or improve an appropriate level of sensitivity, a high film retention rate, low-transmittance properties, excellent adhesion to a substrate, chemical resistance, heat resistance, low hygroscopicity, device reliability, etc., all at excellent levels.

In addition to the effects described above, specific effects of the present disclosure will be described below together with the specific contents for carrying out the present disclosure.

### BRIEF DESCRIPTION OF THE DRAWINGS

FIG. 1 illustrates a display device according to one embodiment of the present disclosure.

### DETAILED DESCRIPTION OF THE INVENTION

In the present specification, singular expressions include plural expressions unless the context clearly indicates otherwise.

In the present specification, the range of numerical values expressed using the term “to” denotes a range of numerical values that includes numerical values described before and after the term “to” as a lower limit value and an upper limit value. When a plurality of numerical values as the upper and lower limits of an arbitrary numerical range are disclosed, the numerical range disclosed in the present specification may be understood as a range of arbitrary numerical values including any one value among the plurality of lower limit values and any one value among the plurality of upper limit values as a lower limit value and an upper limit value, respectively. For example, if “a to b” or “c to d” is described in the specification, it may be understood that “a to b”, “a to d”, “c to d”, or “c to b” is described.

In the present specification, unless otherwise defined below, “substituted” means that at least any one hydrogen atom is replaced with any one selected from the group consisting of a halogen atom, a hydroxyl group, a carboxyl group, a nitro group, an amine group, a sulfide group, a thiol group, an alkoxy group, an acetoxy group, a nitrile group, an aldehyde group, an ether group, an ester group, an acetal group, a ketone group, a C₁ to C₃₀ alkyl group, a C₂ to C₃₀ alkenyl group, a C₂ to C₃₀ alkynyl group, a C₁ to C₄₀ alkylsilyl group, a C₅ to C₄₀ arylsilyl group, a C₃ to C₃₀ cycloalkyl group, a C₃ to C₃₀ allyl group, a C₆ to C₃₀ aryl group, a heterocyclic group (e.g., a C₂ to C₃₀ heterocycloalkyl group, a C₃ to C₃₀ heteroaryl group), derivatives thereof, and combinations thereof.

In the present specification, “fused ring” refers to a ring system formed by two or more rings sharing two or more atoms, and may include, for example, a fused aliphatic ring, a fused aromatic ring, a fused heteroaliphatic ring, a fused heteroaromatic ring, or a combination thereof.

In the present specification, “spiro structure” has a spiro union, wherein the spiro union refers to a union made by two rings sharing only one atom.

For example, the alkyl group may be straight or branched, and specifically, may be methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl, etc.

In the present specification, the number of carbon atoms in the “substituted or unsubstituted alkyl group having one or more carbon atoms” may be 1 or more, 1 to 30, 1 to 20, or 1 to 10.

In the present specification, the number of carbon atoms in the “substituted or unsubstituted aryl group having 6 or more carbon atoms” may be 6 or more, 6 to 50, 6 to 40, 6 to 30, or 6 to 20.

For example, the ester group may mean —COO—R, or R—COO—. Here, the number of carbon atoms in the R group of the ester group may be 1 to 50.

For example, the cycloalkyl group may be cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, or the like.

For example, the alkenyl group may be straight or branched, and the number of carbon atoms thereof is not particularly limited, but is preferably 2 to 40. As a specific example, the alkenyl group may be vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, stilbenyl, styrenyl, or the like.

For example, the aryl group may be a monocyclic aryl group or a polycyclic aryl group, and specifically may be a phenyl group, a biphenyl group, a terphenyl group, a naphthyl group, an anthracenyl group, a phenanthryl group, a pyrenyl group, a perylenyl group, a chrysenyl group, a fluorenyl group, or the like.

For example, the heterocyclic group contains at least one non-carbon atom (heteroatom), wherein the heteroatom may include at least one atom selected from the group consisting of O, N, Se, and S. The number of carbon atoms in the heterocyclic group is not particularly limited, but is preferably 2 to 60. Examples of the heterocyclic groups include, but are not limited to, a thiophene group, a furan group, a pyrrole group, an imidazole group, a thiazole group, an oxazole group, an oxadiazole group, a triazole group, a pyridyl group, a bipyridyl group, a pyrimidyl group, a triazine group, a triazole group, an acridyl group, a pyridazine group, a pyrazinyl group, a quinolinyl group, a quinazoline group, a quinoxalinyl group, a phthalazinyl group, a pyridopyrimidinyl group, a pyridopyrazinyl group, a pyrazino pyrazinyl group, an isoquinoline group, an indole group, a carbazole group, a benzoxazole group, a benzimidazole group, a benzothiazole group, a benzocarbazole group, a benzothiophene group, a dibenzothiophene group, a benzofuranyl group, a phenanthroline group, a thiazolyl group, an isoxazolyl group, an oxadiazolyl group, a thiadiazolyl group, a benzothiazolyl group, a phenothiazinyl group, and a dibenzofuranyl group.

In the present specification, “organic group” may be defined as a monovalent or polyvalent group containing at least one carbon atom. For example, the polyvalent group may be a divalent or trivalent linking group. In some examples, the number of carbon atoms in the organic group may be 1 to 40, 1 to 30, or 1 to 20.

In the present specification, “unsubstituted hydrocarbon group” is a substituent composed of carbon and hydrogen, which may be a functional group having one or more carbon atoms, and specifically, may be a functional group having 1 to 40, 1 to 30, or 1 to 20 carbon atoms. On the other hand, “substituted hydrocarbon group” in the present specification means that at least one hydrogen atom of an unsubstituted hydrocarbon group is replaced with any one selected from the group consisting of a halogen atom, a hydroxyl group, a carboxyl group, a nitro group, an amine group, a sulfide group, a thiol group, an alkoxy group, an acetoxy group, a nitrile group, an aldehyde group, an ether group, an ester group, an acetal group, a ketone group, a C₁ to C₃₀ alkyl group, a C₂ to C₃₀ alkenyl group, a C₂ to C₃₀ alkynyl group, a C₁ to C₄₀ alkylsilyl group, a C₅ to C₄₀ arylsilyl group, a C₃ to C₃₀ cycloalkyl group, a C₃ to C₃₀ allyl group, a C₆ to C₃₀ aryl group, a heterocyclic group (e.g., a C₂ to C₃₀ heterocycloalkyl group, a C₃ to C₃₀ heteroaryl group), derivatives thereof, and combinations thereof.

In the present specification, “composition” may mean a mixture of materials including the composition, a reaction product formed from the materials of the composition, or a decomposition product. For example, the content of the material in the composition may be measured using gas chromatography. Specifically, the content of the material may be analyzed using an Agilent gas chromatography instrument (product name: Agilent 7890 GC, column: HP-5, carrier gas: helium (flow rate: 2.4 mL/min), detector: F.I.D, injection volume: 1 μL, initial value: 70° C./4.2 min, final value: 280° C./7.8 min, program rate: 15° C./min).

In the present specification, “*” may be defined as a part or linking bond that is bonded to another part within the molecule. Here, the other part within the molecule may include a substituent or non-substituent. Specifically, the substituent may be an atom or atomic group bonded to the main chain (or ballast), and the non-substituent may mean any molecular structure not defined by the substituent. For example, when there are two or more *, the other parts within the molecule may be the same as or different from each other. For example, *, which is defined as a part that is not bonded to other parts within the molecule, may form a ring structure within the molecule by bonding to an indirectly bonded atom.

According to one aspect of the present disclosure, there is provided a photosensitive resin composition including: an alkali-soluble resin; and a photoactive compound, wherein at least any one of the alkali-soluble resin and the photoactive compound has an absorption maximum (inflection point) at a wavelength of 400 to 550 nm as measured by UV-Vis spectroscopy. According to one aspect of the present disclosure, by using a compound capable of imparting coloring properties as a monomer used in the synthesis of the alkali-soluble resin and/or a ballast used in the synthesis of the photoactive compound, coloring properties may be easily imparted even without separately adding a colored additive. According to another aspect of the present disclosure, while imparting the above-described coloring properties, it is possible to maintain or improve an appropriate level of sensitivity, a high film retention rate, low-transmittance properties, excellent adhesion to a substrate, chemical resistance, heat resistance, low hygroscopicity, device reliability, etc., all at excellent levels.

Hereinafter, the configuration of the present disclosure will be described in more detail.

### 1. Photosensitive Resin Composition

The photosensitive resin composition according to the present disclosure has photoactive reactivity and alkali solubility and includes an alkali-soluble resin to achieve developability.

The alkali-soluble resin according to the present disclosure may have an absorption maximum (inflection point) at a wavelength of 400 to 550 nm as measured by UV-Vis spectroscopy. For example, the absorption maximum may be analyzed by measuring light transmittance at a wavelength of 400 to 550 nm using a UV-Vis NIR spectrophotometer with a C light source and a viewing angle of 2° according to ASTM E313-73 standard.

The alkali-soluble resin according to the present disclosure may include any one or more of structures represented by Formulas 1, 2-1 to 2-3, and 3 to 7 below.

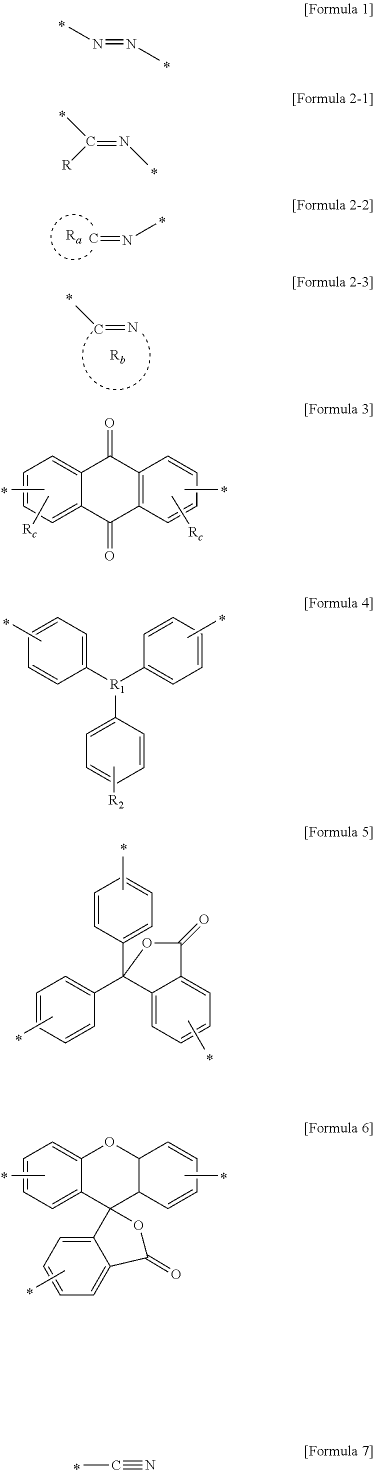

R in Formula 2-1 above is hydrogen or a substituted or unsubstituted organic group; Rₐ and R_{b} in Formulas 2-2 and 2-3 above are each independently a substituted or unsubstituted pentagonal ring or a substituted or unsubstituted hexagonal ring; R_{c} in Formula 3 above are each independently a hydrogen atom or a substituted or unsubstituted hydrocarbon group having one or more carbon atoms; and R₁ in Formula 4 above includes a trivalent organic group or a nitrogen atom, and R₂ includes a hydrogen atom, a hydroxyl group, a sulfonic acid ester group, or a substituted or unsubstituted hydrocarbon group having one or more carbon atoms.

In some examples, the pentagonal ring may contain one or two nitrogen atoms in the ring.

In some examples, the hexagonal ring may include one, two, or three nitrogen atoms in the ring. Specifically, the hexagonal ring may be pyrazine, pyridazine, or pyrimidine.

Specifically, in Formula 2-1 above, R may be hydrogen or a substituted or unsubstituted organic group.

In Formula 4 above, R₁ includes a trivalent organic group or a nitrogen atom, and R₂ includes a hydrogen atom, a hydroxyl group, a sulfonic acid ester group, or a substituted or unsubstituted hydrocarbon group having one or more carbon atoms. Here, the trivalent organic group is not particularly limited and may include a substituted or unsubstituted alkylidyne capable of forming a trivalent bond having one or more carbon atoms, a substituted or unsubstituted trivalent aromatic linking group, a trivalent heteroaromatic linking group, or the like. In some examples, the substituted or unsubstituted alkylidyne may be methylidyne, substituted or unsubstituted ethylidyne, or substituted or unsubstituted propylidyne.

In the alkali-soluble resin according to the present disclosure, R₂ in Formula 4 above may be a mono- to penta-substituted substituent bonded to the benzene ring, and may be a hydrogen atom or a substituted or unsubstituted hydrocarbon group. For example, the number of carbon atoms in the substituted or unsubstituted hydrocarbon group may be 1 or more. In this case, two * parts in Formula 4 above may be bonded to different molecular structures.

According to some embodiments of the present disclosure, as the alkali-soluble resin includes any one or more of the structures represented by Formulae 1, 2-1 to 2-3, and 3 to 7, it is possible to easily impart coloring properties without separately adding a colored additive, and at the same time, it is possible to maintain or improve an appropriate level of sensitivity, a high film retention rate, low-transmittance properties, excellent adhesion to a substrate, chemical resistance, heat resistance, low hygroscopicity, and device reliability, etc., all at excellent levels.

According to some embodiments of the present disclosure, the alkali-soluble resin may include a structure derived from any one of the compounds represented by Formulas 1a to 1j. Here, the compounds represented by Formulas 1a to 1j may be monomers that are used in the synthesis of the alkali-soluble resin. Accordingly, the acid anhydride group and/or amine group included in the monomer may be a reactive functional group(s) that undergoes a reaction in the process in which various monomers are subjected to condensation polymerization to synthesize a polyimide.

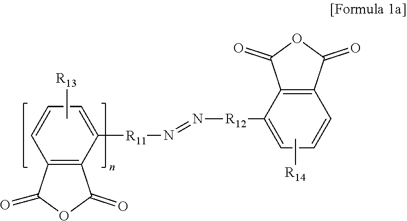

In Formula 1a above, R₁₁ and R₁₂ each independently include a direct bond, a hydrogen atom, or a divalent organic group, wherein, when any one of R₁₁ and R₁₂ is a hydrogen atom, the other is a direct bond or a divalent organic group; n is 0 or 1; and R₁₃ and R₁₄ are each independently a hydrogen atom, a hydroxyl group, a substituted or unsubstituted alkyl group having 1 or more carbon atoms, or a substituted or unsubstituted aryl group having 6 or more carbon atoms.

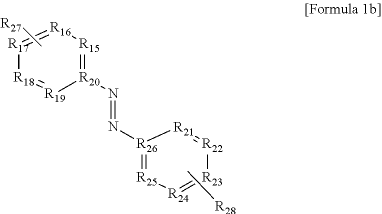

In Formula 1b above, R₁₅ to R₂₆ are each independently carbon or a heteroatom, R₂₇ and R₂₈ are each independently a mono- to penta-substituted substituent in the ring, wherein the substituents each independently include a hydrogen atom, a nitro group, a hydroxyl group, or an amine group, and at least any one of the substituents is an amine group. As at least any one of the substituents corresponds to an amine group, a ring-opening reaction of an acid anhydride structure may proceed. Here, the heteroatom may be, for example, a nitrogen atom, an oxygen atom, or a sulfur atom, and specifically may be a nitrogen atom.

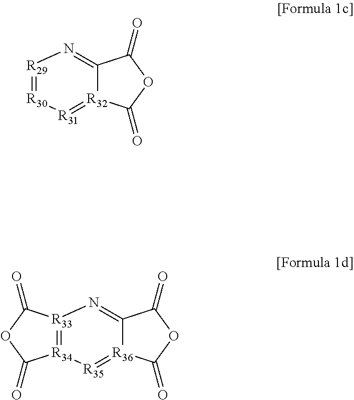

In Formulas 1c and 1d above, R₂₉ to R₃₆ are each independently carbon or a heteroatom. Here, the heteroatom may be, for example, a nitrogen atom, an oxygen atom, a sulfur atom, or the like, and specifically may be a nitrogen atom.

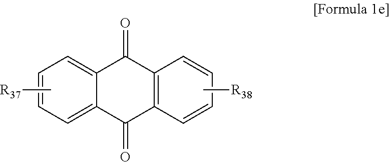

In Formula 1e above, R₃₇ and R₃₈ are each independently a mono- to tetra-substituted substituent, wherein the substituents are each independently a hydrogen atom, an amine group, or an acid anhydride group, and at least any one of the substituents is an amine group or an acid anhydride group, wherein the acid anhydride group is formed as substituents bond to each other when each of R₃₇ and R₃₈ is poly-substituted. Specifically, as at least any one of the substituents corresponds to an amine group or an acid anhydride group, the compound may be a monomer that is used in the synthesis of a polyimide that imparts coloring properties.

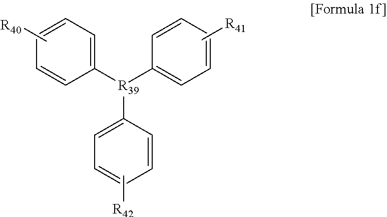

In Formula 1f above, R₃₉ is a trivalent organic group or a nitrogen atom, and R₄₀ to R₄₂ are each independently a mono- to penta-substituted substituent which is a hydrogen atom or an amine group, wherein at least any one of R₄₀ to R₄₂ is an amine group.

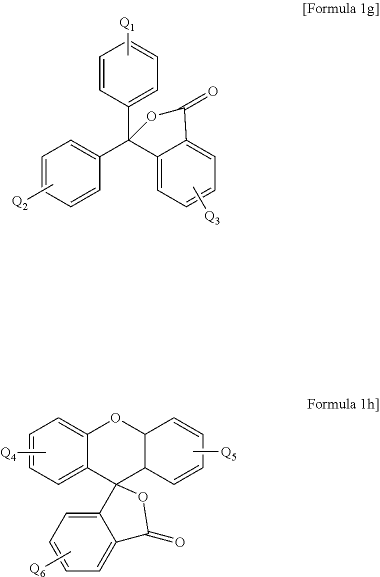

In Formulas 1g and 1h above, Q₁ to Q₆ are each independently a mono- or poly-substituted substituent which is a hydrogen atom, an amine group, or an acid anhydride group, wherein at least any one of Q₁ to Q₃ is an amine group or an acid anhydride group, wherein the acid anhydride group is formed as substituents bond to each other when at least any one of Q₁ to Q₃ is poly-substituted, and wherein at least any one of Q₄ to Q₆ is an amine group or an acid anhydride group, wherein the acid anhydride group is formed as substituents to each other when any one or more of Q₄ to Q₆ are poly-substituted.

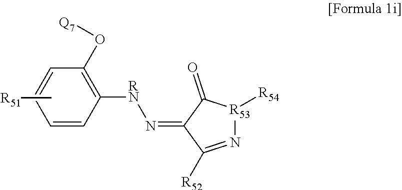

In Formula 1i above, Q₇ includes a hydrogen atom, a substituted or unsubstituted alkyl group having 1 or more carbon atoms, a substituted or unsubstituted aryl group having 6 or more carbon atoms, an amine group, or an acid anhydride group, wherein Q₇ includes at least one amine groups or at least one acid anhydride group; R₅₁, R₅₂, and R₅₄ are each independently a hydrogen atom, a nitro group, a hydroxyl group, a substituted or unsubstituted alkyl group having one or more carbon atoms, or a substituted or unsubstituted aryl group having 6 or more carbon atoms; R₅₃ is a nitrogen atom; and R bonded to N is a hydrogen atom or a substituted or unsubstituted organic group.

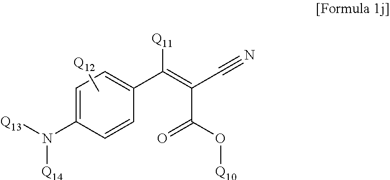

In Formula 1j above, Q₁₀ to Q₁₂ are each independently a hydrogen atom, a hydroxyl group, a substituted or unsubstituted alkyl group having one or more carbon atoms, or a substituted or unsubstituted aryl group having 6 or more carbon atoms, and Q₁₃ and Q₁₄ each independently include a hydrogen atom, at least one amine group, or at least one acid anhydride group.

According to some embodiments of the present disclosure, as the alkali-soluble resin includes a structure derived from any one of the compounds represented by Formulas 1a to 1j, it is possible to easily impart coloring properties without separately adding a colored additive, and at the same time, it is possible to maintain or improve an appropriate level of sensitivity, a high film retention rate, low-transmittance properties, excellent adhesion to a substrate, chemical resistance, heat resistance, low hygroscopicity, and device reliability, etc., all at excellent levels.

The alkali-soluble resin according to the present disclosure may include any one selected from the group consisting of polyamic acid, polyamic ester, and polyimide, and specifically, may include polyimide. Specifically, when the alkali-soluble resin is polyimide, the heat resistance and chemical resistance thereof may be better than those of other resins.

According to some embodiments of the present disclosure, the degree of imidization of the polyimide may be 50% or more, 60% or more, 70% or more, 80% or more, 90% or more, 94% or more, 95% or more, or 96% or more. According to some embodiments of the present disclosure, as the degree of imidization of the polyimide satisfies the above numerical range, the chemical resistance, hygroscopicity, and operational reliability performance may be sufficiently improved. If the degree of imidization of the polyimide is less than the lower limit of the above numerical range, the sensitivity may be improved, but a problem may arise in that the chemical resistance, hygroscopicity, and operation reliability are degraded.

According to some embodiments of the present disclosure, the alkali-soluble resin may include a structure derived from any one of the compounds represented by Formulas 1a to 1j in an amount of 5 mol % or more based on the total moles of the alkali-soluble resin. Specifically, the structure derived from any one of the compounds represented by Formulas 1a to 1j may be included in an amount of 5 mol % or more, 10 mol % or more, 10 to 60 mol %, 20 to 50 mol %, or 30 to 40 mol %. According to some embodiments of the present disclosure, as the structure derived from any one of the compounds represented by Formulas 1a to 1j is included in an amount within the above mol % range, it is possible to easily impart coloring properties without separately adding a colored additive, and at the same time, it is possible to maintain or improve an appropriate level of sensitivity, a high film retention rate, low-transmittance properties, excellent adhesion to a substrate, chemical resistance, heat resistance, low hygroscopicity, and device reliability, etc., all at excellent levels.

In this specification, “weight-average molecular weight” or “number-average molecular weight” refers to a standard polystyrene-converted molecular weight, which may be analyzed using a gel permeation chromatography (GPC) instrument. For example, for a GPC analysis method, the developing solvent may be tetrahydrofuran (THF), the column may be PL Olexis from Polymer Laboratories, the sample concentration may be 5 mg/mL, the sample injection volume may be 100 μL, the flow rate may be 1 mL/min, the detector may be Agilent High Temperature RI detector, and the column temperature may be set to 40° C.

According to some embodiments of the present disclosure, the weight-average molecular weight of the alkali-soluble resin may be 1,000 to 50,000 g/mol, specifically 1,000 to 30,000 g/mol. According to some embodiments of the present disclosure, as the weight-average molecular weight of the alkali-soluble resin satisfies the above numerical range, the developability and the adhesion of the cured film to the substrate may be improved at the same time.

The photoactive compound according to the present disclosure may improve sensitivity through efficient absorption of light and at the same time, improve the solubility of the photosensitive resin composition due to its excellent compatibility with the alkaline-soluble resin. In addition, the photoactive compound according to the present disclosure may include any one or more of the structures represented by Formulas 1, 2-1 to 2-3, and 3 to 7 in order to impart coloring properties even without separately adding a colored additive. According to some embodiments of the present disclosure, as the photoactive compound includes any one or more of the structures represented by Formulas 1, 2-1 to 2-3, and 3 to 7, it is possible to easily impart coloring properties without separately adding a colored additive, and at the same time, it is possible to maintain or improve an appropriate level of sensitivity, a high film retention rate, low-transmittance properties, excellent adhesion to a substrate, chemical resistance, heat resistance, low hygroscopicity, and device reliability, etc., all at excellent levels.

The photoactive compound according to some embodiments of the present disclosure may include a sulfonic acid-esterified quinone diazide compound in order to increase resistance to a developer and photosensitivity. Here, the sulfonic acid-esterified quinone diazide compound may be a compound produced by subjecting the hydroxyl group of a quinone diazide compound to a sulfonic acid esterification reaction. For example, the hydroxyl group may be converted into a naphthoquinone diazide (NQD) sulfonic acid ester group after the reaction.

Specifically, the sulfonic acid-esterified quinone diazide compound may include a phenolic compound as a ballast. More specifically, the phenolic compound may include any one or more of compounds represented by Formulas 2a to 2j below.

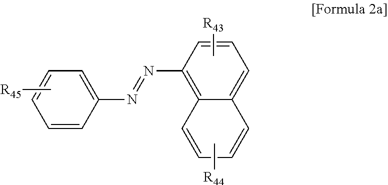

In Formula 2a above, R₄₃ to R₄₅ are each independently a mono- or poly-substituted substituent, wherein the substituents are each independently a hydrogen atom, a nitro group, or a hydroxyl group, and at least any one of the substituents is a hydroxyl group.

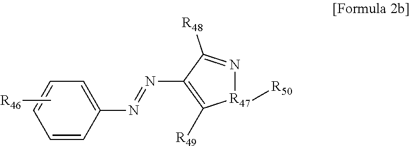

In Formula 2b above, R₄₆ is a mono- to penta-substituted substituent which is a hydrogen atom, a nitro group, or a hydroxyl group, wherein at least any one of R₄₆ includes a hydroxyl group; R₄₇ is a nitrogen atom; and R₄₈ to R₅₀ are each independently a hydrogen atom, a hydroxyl group, a nitro group, a substituted or unsubstituted alkyl group having one or more carbon atoms, or a substituted or unsubstituted aryl group having 6 or more carbon atoms.

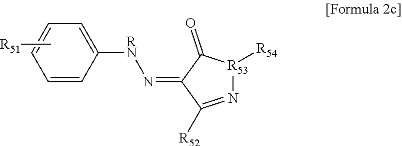

In Formula 2c above, R₅₁ is a mono- to penta-substituted substituent which is a hydrogen atom, a nitro group, a hydroxyl group, a substituted or unsubstituted alkyl group having one or more carbon atoms, or a substituted or unsubstituted aryl group having 6 or more carbon atoms, wherein at least any one of R₅₁ is a hydroxyl group; R₅₂ and R₅₄ are each independently a hydrogen atom, a nitro group, a hydroxyl group, a substituted or unsubstituted alkyl group having one or more carbon atoms, or a substituted or unsubstituted aryl group having 6 or more carbon atoms; R₅₃ is a nitrogen atom; and R bonded to N is a hydrogen atom or a substituted or unsubstituted organic group.

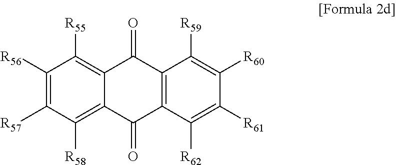

In Formula 2d above, R₅₅ to R₆₂ are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of R₅₅ to R₆₂ is a hydroxyl group.

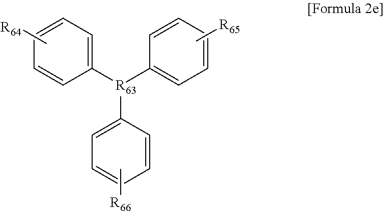

In Formula 2e above, R₆₃ is a trivalent organic group or a nitrogen atom; and R₆₄ to R₆₆ are each independently a mono- to penta-substituted substituent which is a hydrogen atom, a nitro group, a hydroxyl group, a substituted or unsubstituted alkyl group having one or more carbon atoms, or a substituted or unsubstituted aryl group having 6 or more carbon atoms, wherein at least any one of R₆₄ to R₆₆ is a hydroxyl group.

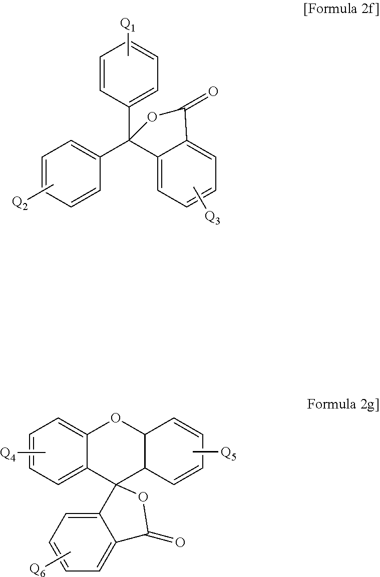

In Formulas 2f and 2g above, Q₁ to Q₆ are each independently a mono- or poly-substituted substituent, and are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of Q₁ to Q₃ is a hydroxyl group, and at least any one of Q₄ and Q₆ is a hydroxyl group.

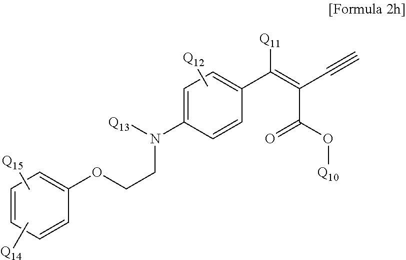

In Formula 2h above, Q₁₀ to Q₁₂ are each independently a hydrogen atom, a nitro group, a hydroxyl group, a substituted or unsubstituted alkyl group having one or more carbon atoms, or a substituted or unsubstituted aryl group having 6 or more carbon atoms; Q₁₃ is a hydrogen atom, a substituted or unsubstituted alkyl group having one or more carbon atoms, or a substituted or unsubstituted aryl group having 6 or more carbon atoms; and Q₁₄ and Q₁₅ are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of Q₁₄ and Q₁₅ is a hydroxyl group.

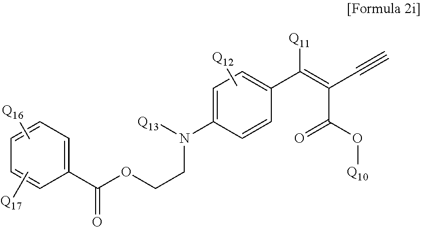

In Formula 2i above, Q₁₀ to Q₁₂ are each independently a hydrogen atom, a nitro group, a hydroxyl group, a substituted or unsubstituted alkyl group having one or more carbon atoms, or a substituted or unsubstituted aryl group having 6 or more carbon atoms; Q₁₃ is a hydrogen atom, a substituted or unsubstituted alkyl group having one or more carbon atoms, or a substituted or unsubstituted aryl group having 6 or more carbon atoms; and Q₁₆ and Q₁₇ are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of Q₁₆ and Q₁₇ is a hydroxyl group.

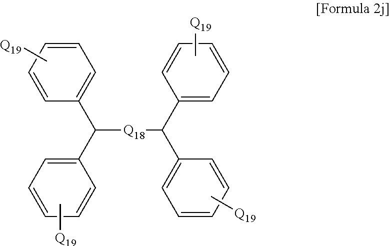

In Formula 2j above, Q₁₈ is a divalent linking group including at least one aromatic ring, and Q₁₉ are each independently a mono- to penta-substituent in the benzene ring, wherein at least any one of the mono- to penta-substituted substituents may be a hydroxyl group. For example, the aromatic ring may be a benzene ring, and specifically, Q₁₈ may be a substituted or unsubstituted phenylene group or a substituted or unsubstituted naphthalene group. For example, Q₁₉ may be a monosubstituted hydroxyl group at the para position, and the remaining substituents may all be hydrogen atoms.

According to some embodiments of the present disclosure, as any one or more of the compounds represented by Formulas 2a to 2j is used as a ballast for the photoactive compound, it is possible to easily impart coloring properties without separately adding a colored additive, and at the same time, it is possible to maintain or improve an appropriate level of sensitivity, a high film retention rate, low-transmittance properties, excellent adhesion to a substrate, chemical resistance, heat resistance, low hygroscopicity, and device reliability, etc., all at excellent levels.

According to some embodiments of the present disclosure, the content of the sulfonic acid-esterified quinone diazide compound may be 5 to 40 parts by weight, more than 10 and less than 40 parts by weight, 15 to 35 parts by weight, 20 to 35 parts by weight, 25 to 35 parts by weight, 28 to 32 parts by weight, or 29 to 31 parts by weight, and preferably 30 to 31 parts by weight, based on 100 parts by weight of the alkali-soluble resin. According to some embodiments of the present disclosure, as the content of the sulfonic acid-esterified quinone diazide compound satisfies the above numerical range, the pattern shape may be appropriately maintained and at the same time, appropriate photosensitivity and heat resistance may be ensured. Specifically, the sulfonic acid-esterified quinone diazide compound may be one in which at least one of the hydroxyl groups in the quinone diazide compound is esterified with sulfonic acid.

In some embodiments of the present disclosure, the degree of sulfonic acid esterification of the sulfonic acid-esterified quinone diazide compound may be 1.0 to 3.3%, 1.2 to 3.0%, 1.5 to 2.5%, 1.8 to 2.2%, or 1.9 to 2.0%. Here, the degree of sulfonic acid esterification may mean the degree to which a phenol group (—OH) is substituted with a sulfonic acid ester group relative to the total number of phenol groups (—OH) of the sulfonic acid-esterified quinone diazide compound. For example, the degree of sulfonic acid esterification may be analyzed using an ultra-performance liquid chromatography (UPLC) analysis method. According to some embodiments of the present disclosure, as the degree of sulfonic acid esterification is controlled within the above numerical range, the performances in terms of sensitivity, film retention rate, transmittance, and device operation reliability may all be improved.

The photosensitive resin composition according to the present disclosure may further include a solvent that disperses or dissolves the above-described composition. For example, the solvent is not particularly limited, but may include at least one selected from the group consisting of gamma-butyrolactone (GBL), N-methylpyrrolidone (NMP), propylene glycol monomethyl ether acetate (PGME), ethyl lactate (EL), methyl 3-methoxypropionate (MMP), propylene glycol monomethyl ether (PGME), diethylene glycol ethyl methyl ether (MEDG), diethylene glycol butyl methyl ether (MBDG), diethylene glycol dimethyl ether (DMDG), and diethylene glycol diethyl ether (DEDG).

The photosensitive resin composition according to the present disclosure may further include at least one of a crosslinking agent, a thermal acid generator, and a UV absorber.

The crosslinking agent according to the present disclosure may effectively control the shape of a pattern by performing a crosslinking reaction with the alkaline-soluble resin by light or heat. For example, the crosslinking agent may be any one of groups represented by the following formulas. When the photosensitive resin composition further includes a thermal acid generator or a UV absorber, the heat resistance, hygroscopicity, etc. of the resin composition may be improved, thereby achieving the effect of ensuring better panel reliability.

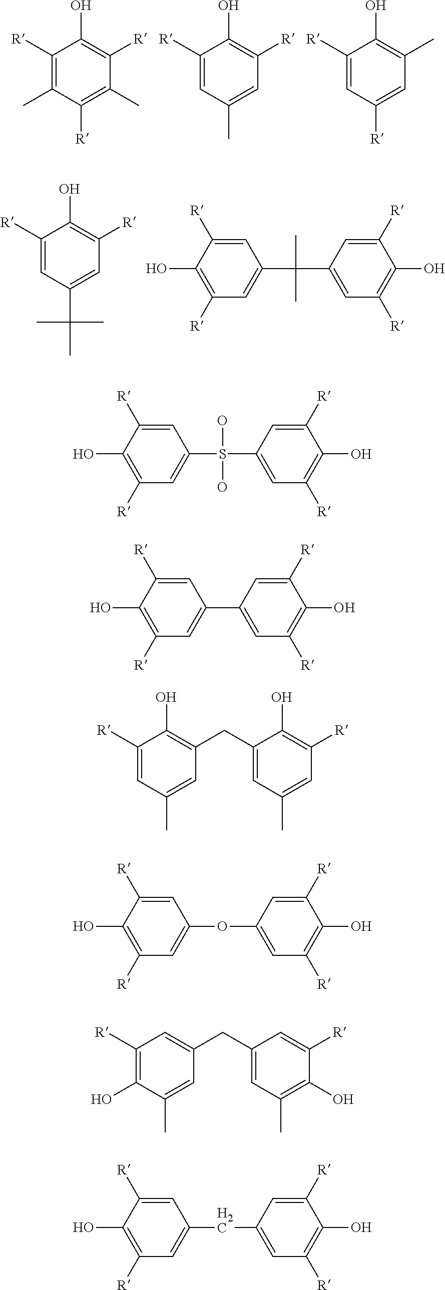

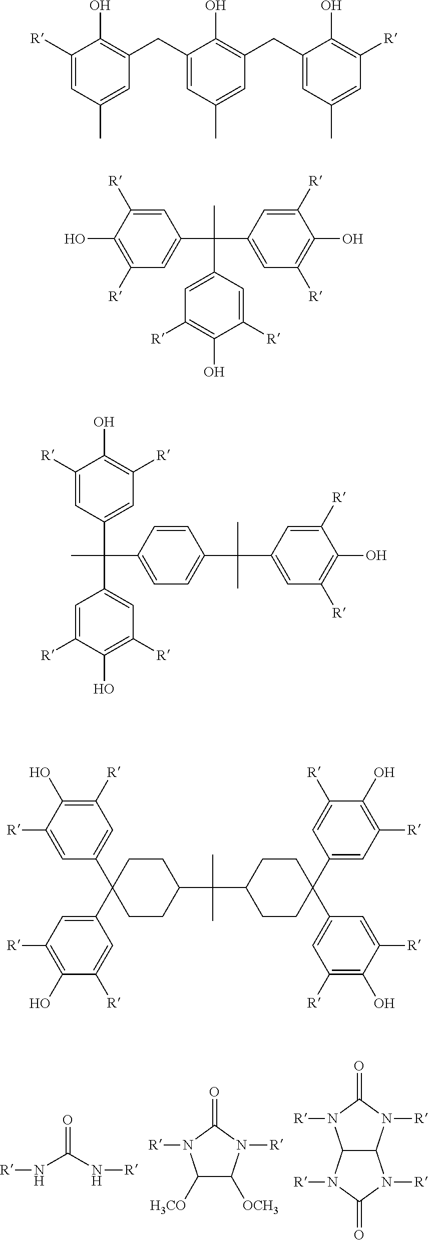

In the groups represented by the above formulas, R′ are each independently a hydrogen atom, an alkyl group having 1 to 3 carbon atoms, or a substituent of the following Formula C, and at least one of R′ is a substituent of the following Formula C. In the following Formula C, n is an integer ranging from 1 to 6, and Rₐ is an alkyl group having 1 to 3 carbon atoms. Specifically, in Formula C, n may be 1, 2, 3, 4, 5, or 6.

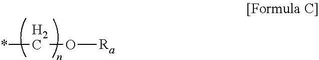

For example, the photosensitive resin composition may be a positive photosensitive resin composition.

### 2. Insulating Film and Display Device

According to another aspect of the present disclosure, there is provided an insulating film including a cured product of the photosensitive resin composition of some embodiments.

In some embodiments of the present disclosure, the sensitivity of the insulating film may be 100 mJ or less or 80 mJ or less based on a specimen having a thickness of 2.0 μm.

In some embodiments of the present disclosure, the transmittance of the insulating film may be less than 20% or less than 10% as measured using a spectrophotometer in a wavelength range of 400 to 500 nm.

In some embodiments of the present disclosure, the change in thickness of the insulating film between before and after immersion in N-methylpyrrolidone (NMP) at 60° C. for 120 seconds may be less than 300 Å.

In some embodiments of the present disclosure, the 5 wt % loss temperature of the insulating film after heating from room temperature to 900° C. at a rate of 10° C. per minute may be higher than 300° C.

In some embodiments of the present disclosure, the change in thickness of the insulating film between before and after being placed in a constant temperature and constant humidity oven after 240 hours of purification in the oven at 85° C. and 85% RH may be less than 300 Å.

According to another aspect of the present disclosure, there is provided a display device including the insulating film.

As a preferred example, the display device may be a display device for an organic electroluminescent device, and specifically, may be an organic light-emitting diode (OLED).

In some embodiments of the present disclosure, the display device for an organic electroluminescent device includes: a first electrode formed on a substrate; an insulating film formed on the first electrode; and a second electrode formed on the insulating film, wherein the insulating film may be a cured product of the photosensitive resin composition according to some embodiments

In some embodiments of the present disclosure, the insulating film may be patterned to partially expose the upper surface of the first electrode.

In some embodiments of the present disclosure, the insulating film may be formed to cover an edge portion of the first electrode.

In some embodiments of the present disclosure, when the display device is a display device for an organic electroluminescent device, the time (T₉₇) for a 3% luminance drop in the “on” state of the OLED device at 85° C. and 85% R.H. may be 1,000 hours or more.

Hereinafter, examples of the present disclosure will be described in detail so that a person skilled in the art to which the present disclosure pertains can easily carry out the present disclosure. However, this is merely an example, and the scope of rights of the present disclosure is not limited by the following contents.

### Synthesis Preparation Example: Preparation of Monomers

To synthesize polyimide, the monomers described in Table 1 below were prepared.

TABLE 1

| Monomer | Formula |
|---|---|
| ODPA | 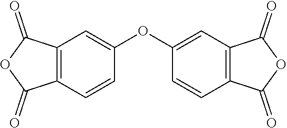 [SMILES: O=C1OC(=O)c2cc(Oc3ccc4c(c3)C(=O)OC4=O)ccc21] |
| A1 | 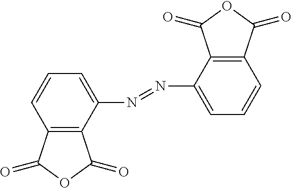 [SMILES: O=C1OC(=O)c2c(/N=N/c3cccc4c3C(=O)OC4=O)cccc21] |
| PA | 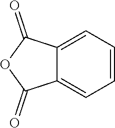 [SMILES: O=C1OC(=O)c2ccccc21] |
| A2 | 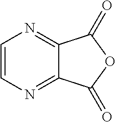 [SMILES: O=C1OC(=O)c2nccnc21] |
| A3 | 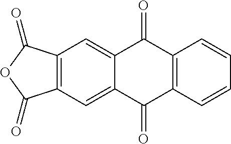 [SMILES: O=c1oc(=O)c2cc3c(=O)c4ccccc4c(=O)c3cc12] |
| Bis-APAF | 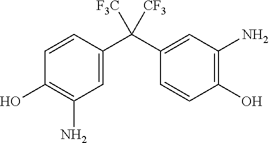 [SMILES: Nc1cc(C(c2ccc(O)c(N)c2)(C(F)(F)F)C(F)(F)F)ccc1O] |
| B1 | 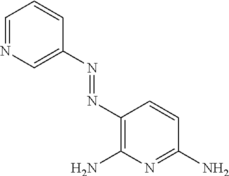 [SMILES: Nc1ccc(/N=N/c2cccnc2)c(N)n1] |
| B2 | 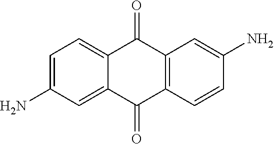 [SMILES: Nc1ccc2c(c1)C(=O)c1ccc(N)cc1C2=O] |
| B3 | 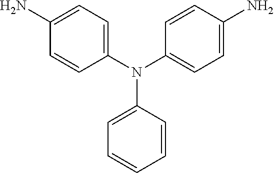 [SMILES: Nc1ccc(N(c2ccccc2)c2ccc(N)cc2)cc1] |
| 3-AP | 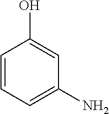 |
| B4 | 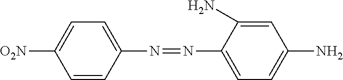 [SMILES: Nc1ccc(N=Nc2ccc([N+](=O)[O-])cc2)c(N)c1] |
| B5 | 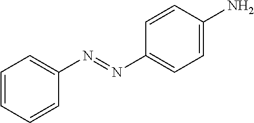 [SMILES: Nc1ccc(/N=N/c2ccccc2)cc1] |
| B6 | 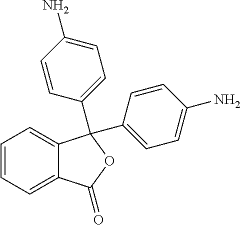 [SMILES: Nc1ccc(C2(c3ccc(N)cc3)OC(=O)c3ccccc32)cc1] |
| B7 | 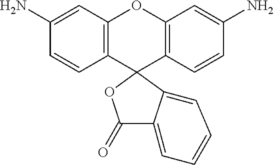 [SMILES: Nc1ccc2c(c1)Oc1cc(N)ccc1C21OC(=O)c2ccccc21] |
| B8 | 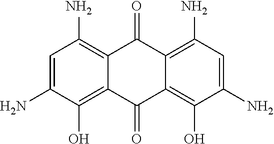 [SMILES: Nc1cc(N)c2c(c1O)C(=O)c1c(O)c(N)cc(N)c1C2=O] |

### First Synthesis Example: Synthesis of Polyimide

### Diamine Dissolution Step:

Under a dry nitrogen stream, a diamine having the composition and content described in Table 2 below was dissolved in in gamma-butyrolactone, thereby preparing a diamine solution.

### Dianhydride Dissolution Step:

While stirring the diamine solution, a dianhydride having the composition and content described in Table 2 below was added thereto and dissolved, followed by stirring at 70° C. for 4 hours.

### End-Capping Step:

To the resultant product obtained by adding and stirring the di anhydride, an amine and/or acid anhydride having the composition and content described in Table 2 below was added, followed by stirring at 70° C. for 2 hours.

### Imidization Step:

The resultant product obtained by adding and stirring the acid anhydride was stirred at 160° C. or higher for 4 hours or more, and then the reaction was terminated, thereby finally synthesizing a dyed polyimide polymer.

Meanwhile, each composition in Tables 2 and 3 below is given in units of mol.

In addition, the degree of imidization in polyimide may be determined through: a step of measuring the infrared absorption spectrum of the polyimide and measuring a peak intensity P1 near 1377 cm⁻¹, which is an absorption peak derived from an imide structure; a step of heat-treating the polyimide at 350° C. for 1 hour, and then measuring the infrared absorption spectrum and measuring a peak intensity P2 near 1377 cm⁻¹; and a step of calculating the degree of imidization of the polyimide according to Equation 1 below using the peak intensities P1 and P2.

$$Imidization degree [ \% ] = ( P 1 / P 2 ) \times 100 \qquad [ Equation 1 ]$$

TABLE 2

| | | | | | | | | | | | | | PI |
|---|---|---|---|---|---|---|---|---|---|---|---|---|---|
| | | | | | | Diamine | | | | Amine | | | Degree |
| | Dianhydride | | Acid anhydride | | | Bis- | | | | 3- | | | of imidi- |
| | ODPA | A1 | PA | A2 | A3 | APAF | B1 | B2 | B3 | AP | B4 | B5 | zation |
| Synthesis | 45 | 45 | 20 | | | 100 | | | | | | | 94% |
| Example 1 | | | | | | | | | | | | | |
| Synthesis | 45 | 45 | | 20 | | 100 | | | | | | | 94% |
| Example 2 | | | | | | | | | | | | | |
| Synthesis | 45 | 45 | | | 20 | 100 | | | | | | | 94% |
| Example 3 | | | | | | | | | | | | | |
| Synthesis | 100 | | | | | 45 | 45 | | | 20 | | | 96% |
| Example 4 | | | | | | | | | | | | | |
| Synthesis | 100 | | | | | 45 | 45 | | | | 20 | | 96% |
| Example 5 | | | | | | | | | | | | | |
| Synthesis | 100 | | | | | 45 | 45 | | | | | 20 | 96% |
| Example 6 | | | | | | | | | | | | | |
| Synthesis | 100 | | | | | 45 | | 45 | | 20 | | | 96% |
| Example 7 | | | | | | | | | | | | | |
| Synthesis | 100 | | | | | 45 | | 45 | | | 20 | | 96% |
| Example 8 | | | | | | | | | | | | | |
| Synthesis | 100 | | | | | 45 | | 45 | | | | 20 | 96% |
| Example 9 | | | | | | | | | | | | | |
| Synthesis | 100 | | | | | 45 | | | 45 | 20 | | | 96% |
| Example 10 | | | | | | | | | | | | | |
| Synthesis | 100 | | | | | 45 | | | 45 | | 20 | | 96% |
| Example 11 | | | | | | | | | | | | | |
| Synthesis | 100 | | | | | 45 | | | 45 | | | 20 | 96% |
| Example 12 | | | | | | | | | | | | | |
| Synthesis | 45 | 45 | 20 | | | 50 | 50 | | | | | | 94% |
| Example 13 | | | | | | | | | | | | | |
| Synthesis | 45 | 45 | | 20 | | 50 | 50 | | | | | | 94% |
| Example 14 | | | | | | | | | | | | | |
| Synthesis | 45 | 45 | | | 20 | 50 | 50 | | | | | | 94% |
| Example 15 | | | | | | | | | | | | | |
| Synthesis | 45 | 45 | 20 | | | 50 | | 50 | | | | | 94% |
| Example 16 | | | | | | | | | | | | | |
| Synthesis | 45 | 45 | | 20 | | 50 | | 50 | | | | | 94% |
| Example 17 | | | | | | | | | | | | | |
| Synthesis | 45 | 45 | | | 20 | 50 | | 50 | | | | | 94% |
| Example 18 | | | | | | | | | | | | | |
| Synthesis | 45 | 45 | 20 | | | 50 | | | 50 | | | | 94% |
| Example 19 | | | | | | | | | | | | | |
| Synthesis | 45 | 45 | | 20 | | 50 | | | 50 | | | | 94% |
| Example 20 | | | | | | | | | | | | | |
| Synthesis | 45 | 45 | | | 20 | 50 | | | 50 | | | | 94% |
| Example 21 | | | | | | | | | | | | | |
| Synthesis | 50 | 50 | | | | 45 | 45 | | | 20 | | | 96% |
| Example 22 | | | | | | | | | | | | | |
| Synthesis | 50 | 50 | | | | 45 | 45 | | | | 20 | | 96% |
| Example 23 | | | | | | | | | | | | | |
| Synthesis | 50 | 50 | | | | 45 | 45 | | | | | 20 | 96% |
| Example 24 | | | | | | | | | | | | | |
| Synthesis | 50 | 50 | | | | 45 | | 45 | | 20 | | | 96% |
| Example 25 | | | | | | | | | | | | | |
| Synthesis | 50 | 50 | | | | 45 | | 45 | | | 20 | | 96% |
| Example 26 | | | | | | | | | | | | | |
| Synthesis | 50 | 50 | | | | 45 | | 45 | | | | 20 | 96% |
| Example 27 | | | | | | | | | | | | | |
| Synthesis | 50 | 50 | | | | 45 | | | 45 | 20 | | | 96% |
| Example 28 | | | | | | | | | | | | | |
| Synthesis | 50 | 50 | | | | 45 | | | 45 | | 20 | | 96% |
| Example 29 | | | | | | | | | | | | | |
| Synthesis | 50 | 50 | | | | 45 | | | 45 | | | 20 | 96% |
| Example 30 | | | | | | | | | | | | | |
| Synthesis | 100 | | | | | 90 | | | | 20 | | | 96% |
| Example 31 | | | | | | | | | | | | | |
| Synthesis | 100 | | | | | 90 | | | | | 20 | | 96% |
| Example 32 | | | | | | | | | | | | | |
| Synthesis | 100 | | | | | 90 | | | | | | 20 | 96% |
| Example 33 | | | | | | | | | | | | | |
| Synthesis | 90 | | 20 | | | 100 | | | | | | | 94% |
| Example 34 | | | | | | | | | | | | | |
| Synthesis | 90 | | | 20 | | 100 | | | | | | | 94% |
| Example 35 | | | | | | | | | | | | | |
| Synthesis | 90 | | | 20 | | 100 | | | | | | | 94% |
| Example 36 | | | | | | | | | | | | | |

1) ODPA: 4,4′-Oxydiphthalic Anhydride
2) PA: Phthalic anhydride
3) Bis-APAF: 2,2-bis(3-amino-4-hydroxyphenyl)hexafluoropropane
4) 3-AP: 3-Aminophenol
5) PI: Polyimide

TABLE 3

| | | | | | | | | | | | | | PI |
|---|---|---|---|---|---|---|---|---|---|---|---|---|---|
| | | | | | | Diamine | | | | Amine | | | Degree |
| | Dianhydride | | Acid anhydride | | | Bis- | | | | 3- | | | of imidi- |
| | ODPA | A1 | PA | A2 | A3 | APAF | B6 | B7 | B8 | AP | B4 | B5 | zation |
| Synthesis | 100 | | 100 | | 100 | 100 | 45 | | | 20 | | | 96% |
| Example 37 | | | | | | | | | | | | | |
| Synthesis | 100 | | 100 | | 100 | 100 | 45 | | | | 20 | | 96% |
| Example 38 | | | | | | | | | | | | | |
| Synthesis | 100 | | 100 | | 100 | 100 | 45 | | | | | 20 | 96% |
| Example 39 | | | | | | | | | | | | | |
| Synthesis | 100 | | 100 | | 100 | 45 | | 45 | | 20 | | | 96% |
| Example 40 | | | | | | | | | | | | | |
| Synthesis | 100 | | | | | 45 | | 45 | | | 20 | | 96% |
| Example 41 | | | | | | | | | | | | | |
| Synthesis | 100 | | | | | 45 | | 45 | | | | 20 | 96% |
| Example 42 | | | | | | | | | | | | | |
| Synthesis | 100 | | | | | | | | 100 | | | | 96% |
| Example 43 | | | | | | | | | | | | | |

### Comparative Synthesis Example: Synthesis of Polyimide

Polyimide was synthesized in the same manner as in the First Synthesis Example, except that monomers having the contents described in Table 4 below were used.

TABLE 4

| | | | | | | | | | | | | | PI |
|---|---|---|---|---|---|---|---|---|---|---|---|---|---|
| | | | | | | Diamine | | | | Amine | | | Degree |
| | Dianhydride | | Acid anhydride | | | Bis- | | | | 3- | | | of imidi- |
| | ODPA | A1 | PA | A2 | A3 | APAF | B1 | B2 | B3 | AP | B4 | B5 | zation |
| Comparative | 100 | | | | | 96 | | | | 8 | | | 95% |
| Synthesis | | | | | | | | | | | | | |
| Example 1 | | | | | | | | | | | | | |
| Comparative | 100 | | | | | 96 | | | | | 8 | | 95% |
| Synthesis | | | | | | | | | | | | | |
| Example 2 | | | | | | | | | | | | | |
| Comparative | 100 | | | | | 96 | | | | | | 8 | 95% |
| Synthesis | | | | | | | | | | | | | |
| Example 3 | | | | | | | | | | | | | |
| Comparative | 96 | | 8 | | | 100 | | | | | | | 95% |
| Synthesis | | | | | | | | | | | | | |
| Example 4 | | | | | | | | | | | | | |
| Comparative | 96 | | | 8 | | 100 | | | | | | | 95% |
| Synthesis | | | | | | | | | | | | | |
| Example 5 | | | | | | | | | | | | | |
| Comparative | 96 | | | | 8 | 100 | | | | | | | 95% |
| Synthesis | | | | | | | | | | | | | |
| Example 6 | | | | | | | | | | | | | |
| Comparative | 45 | 45 | 20 | | | 100 | | | | | | | 95% |
| Synthesis | | | | | | | | | | | | | |
| Example 7 | | | | | | | | | | | | | |
| Comparative | 45 | 45 | 20 | | | 100 | | | | | | | 30% |
| Synthesis | | | | | | | | | | | | | |
| Example 8 | | | | | | | | | | | | | |
| Comparative | | 90 | 20 | | | 30 | 70 | | | | | | 95% |
| Synthesis | | | | | | | | | | | | | |
| Example 9 | | | | | | | | | | | | | |

### Preparation Example: Synthesis of Photoactive Compound (PAQ)

### Preparation of Ballast:

Each ballast described in Table 5 below was prepared.

### Synthesis of Sulfonic Acid-Esterified Photoactive Compound:

Under a dry nitrogen stream, each ballast described in Table 5 below and 5-naphthoquinone diazide sulfonic acid chloride at a molar ratio of 1:2 were dissolved in 1,4-dioxane at room temperature. Triethylamine was added dropwise thereto so that the temperature did not exceed 35° C. After dropwise addition, the mixture was stirred at 40° C. for 2 hours. The triethylamine salt was filtered off and the filtrate was poured into water. Thereafter, the precipitate was filtered and washed with 100 hydrochloric acid solution. Then, it was washed three times with water. The precipitate was dried in a vacuum dryer, thereby producing a sulfonic acid-esterified quinone diazide compound.

TABLE 5

| | Ballast for photoactive compound (PAC) |
|---|---|
| TPPA | 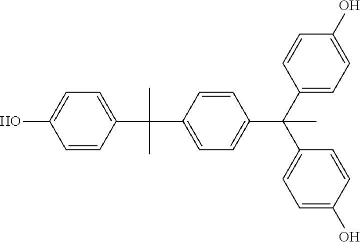 [SMILES: CC(C)(c1ccc(O)cc1)c1ccc(C(C)(c2ccc(O)cc2)c2ccc(O)cc2)cc1] |
| Ballast 1 | 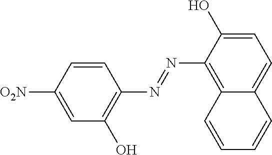 [SMILES: O=[N+]([O-])c1ccc(/N=N/c2c(O)ccc3ccccc23)c(O)c1] |
| Ballast 2 | 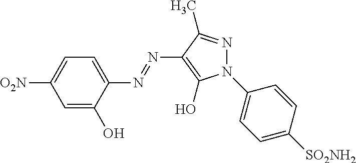 [SMILES: Cc1nn(-c2ccc(S(N)(=O)=O)cc2)c(O)c1/N=N/c1ccc([N+](=O)[O-])cc1O] |
| Ballast 3 | 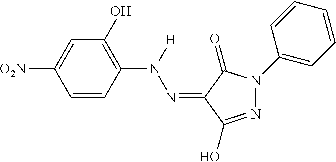 [SMILES: O=C1/C(=N\Nc2ccc([N+](=O)[O-])cc2O)C(O)=NN1c1ccccc1] |
| Ballast 4 | 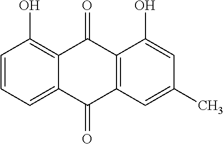 [SMILES: Cc1cc(O)c2c(c1)C(=O)c1cccc(O)c1C2=O] |
| Ballast 5 | 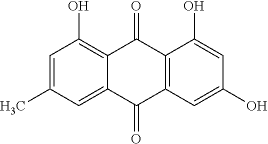 [SMILES: Cc1cc(O)c2c(c1)C(=O)c1cc(O)cc(O)c1C2=O] |
| Ballast 6 | 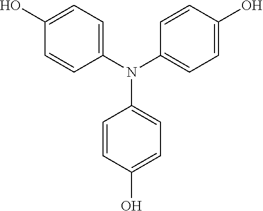 [SMILES: Oc1ccc(N(c2ccc(O)cc2)c2ccc(O)cc2)cc1] |
| Ballast 7 | 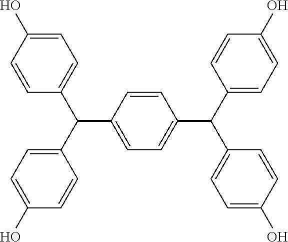 [SMILES: Oc1ccc(C(c2ccc(O)cc2)c2ccc(C(c3ccc(O)cc3)c3ccc(O)cc3)cc2)cc1] |

### Preparation Example 1: Preparation of Photosensitive Resin Composition

An alkali-soluble resin, a photoactive compound and a crosslinking agent, having the composition and contents described in Table 6 below, and a crosslinking agent and a coating aid were mixed together and then added to a solvent, thereby preparing a photosensitive resin composition having a total solid content of 5 to 50 wt %.

TABLE 6

| | | | Photoactive compound | | Colored |
|---|---|---|---|---|---|
| | Alkali-soluble resin | | (transparent PAC) | | additive |
| | Structure | Content | Structure | Content | Content |
| Example | Synthesis | 100 | TPPA | 20 | — |
| 1 | Example | parts by | | parts by | |
| | 1 | weight | | weight | |
| Example | Synthesis | 100 | TPPA | 20 | — |
| 2 | Example 2 | parts by | | parts by | |
| | | weight | | weight | |
| Example | Synthesis | 100 | TPPA | 20 | — |
| 3 | Example 3 | parts by | | parts by | |
| | | weight | | weight | |
| Example | Synthesis | 100 | TPPA | 20 | — |
| 4 | Example 4 | parts by | | parts by | |
| | | weight | | weight | |
| Example | Synthesis | 100 | TPPA | 20 | — |
| 5 | Example 5 | parts by | | parts by | |
| | | weight | | weight | |
| Example | Synthesis | 100 | TPPA | 20 | — |
| 6 | Example 6 | parts by | | parts by | |
| | | weight | | weight | |
| Example | Synthesis | 100 | TPPA | 20 | — |
| 7 | Example 7 | parts by | | parts by | |
| | | weight | | weight | |
| Example | Synthesis | 100 | TPPA | 20 | — |
| 8 | Example 8 | parts by | | parts by | |
| | | weight | | weight | |
| Example | Synthesis | 100 | TPPA | 20 | — |
| 9 | Example 9 | parts by | | parts by | |
| | | weight | | weight | |
| Example | Synthesis | 100 | TPPA | 20 | — |
| 10 | Example | parts by | | parts by | |
| | 10 | weight | | weight | |
| Example | Synthesis | 100 | TPPA | 20 | — |
| 11 | Example | parts by | | parts by | |
| | 11 | weight | | weight | |
| Example | Synthesis | 100 | TPPA | 20 | — |
| 12 | Example | parts by | | parts by | |
| | 12 | weight | | weight | |
| Example | Synthesis | 100 | TPPA | 20 | — |
| 13 | Example | parts by | | parts by | |
| | 13 | weight | | weight | |
| Example | Synthesis | 100 | TPPA | 20 | — |
| 14 | Example | parts by | | parts by | |
| | 14 | weight | | weight | |
| Example | Synthesis | 100 | TPPA | 20 | — |
| 15 | Example | parts by | | parts by | |
| | 15 | weight | | weight | |
| Example | Synthesis | 100 | TPPA | 20 | — |
| 16 | Example | parts by | | parts by | |
| | 16 | weight | | weight | |
| Example | Synthesis | 100 | TPPA | 20 | — |
| 17 | Example | parts by | | parts by | |
| | 17 | weight | | weight | |
| Example | Synthesis | 100 | TPPA | 20 | — |
| 18 | Example | parts by | | parts by | |
| | 18 | weight | | weight | |
| Example | Synthesis | 100 | TPPA | 20 | — |
| 19 | Example | parts by | | parts by | |
| | 19 | weight | | weight | |
| Example | Synthesis | 100 | TPPA | 20 | — |
| 20 | Example | parts by | | parts by | |
| | 20 | weight | | weight | |
| Example | Synthesis | 100 | TPPA | 20 | — |
| 21 | Example | parts by | | parts by | |
| | 21 | weight | | weight | |
| Example | Synthesis | 100 | TPPA | 20 | — |
| 22 | Example | parts by | | parts by | |
| | 22 | weight | | weight | |
| Example | Synthesis | 100 | TPPA | 20 | — |
| 23 | Example | parts by | | parts by | |
| | 23 | weight | | weight | |
| Example | Synthesis | 100 | TPPA | 20 | — |
| 24 | Example | parts by | | parts by | |
| | 24 | weight | | weight | |
| Example | Synthesis | 100 | TPPA | 20 | — |
| 25 | Example | parts by | | parts by | |
| | 25 | weight | | weight | |
| Example | Synthesis | 100 | TPPA | 20 | — |
| 26 | Example | parts by | | parts by | |
| | 26 | weight | | weight | |
| Example | Synthesis | 100 | TPPA | 20 | — |
| 27 | Example | parts by | | parts by | |
| | 27 | weight | | weight | |
| Example | Synthesis | 100 | TPPA | 20 | — |
| 28 | Example | parts by | | parts by | |
| | 28 | weight | | weight | |
| Example | Synthesis | 100 | TPPA | 20 | — |
| 29 | Example | parts by | | parts by | |
| | 29 | weight | | weight | |
| Example | Synthesis | 100 | TPPA | 20 | — |
| 30 | Example | parts by | | parts by | |
| | 30 | weight | | weight | |

### Preparation Example 2: Preparation of Photosensitive Resin Composition

A photosensitive resin composition was prepared in the same manner as in Preparation Example 1, except that an alkali-soluble resin and photoactive compound described in any one of Tables 7 to 9 below were used.

In all Examples and Comparative Examples except for Examples 139 to 142, the degree of sulfonic acid esterification of the photoactive compound was fixed at 2.000. Specifically, the degree of sulfonic acid esterification of the photoactive compound according to Example 139 was adjusted to 1.20%, the degree of sulfonic acid esterification of the photoactive compound according to Example 140 was adjusted to 3.00, the degree of sulfonic acid esterification of the photoactive compound according to Example 141 was adjusted to 1.0%, and the degree of sulfonic acid esterification of the photoactive compound according to Example 142 was adjusted to 330

TABLE 7

| | | | Photoactive compound | | Colored |
|---|---|---|---|---|---|
| | Alkali-soluble resin | | (colored PAC) | | additive |
| | Structure | Content | Structure | Content | Content |
| Example | Synthesis | 100 | Ballast 1 | 20 parts by | — |
| 31 | Example 1 | parts by | | weight | |
| | | weight | | | |
| Example | Synthesis | 100 | Ballast 1 | 20 parts by | — |
| 32 | Example 2 | parts by | | weight | |
| | | weight | | | |
| Example | Synthesis | 100 | Ballast 1 | 20 parts by | — |
| 33 | Example 3 | parts by | | weight | |
| | | weight | | | |
| Example | Synthesis | 100 | Ballast 1 | 20 parts by | — |
| 34 | Example 4 | parts by | | weight | |
| | | weight | | | |
| Example | Synthesis | 100 | Ballast 1 | 20 parts by | — |
| 35 | Example 5 | parts by | | weight | |
| | | weight | | | |
| Example | Synthesis | 100 | Ballast 1 | 20 parts by | — |
| 36 | Example 6 | parts by | | weight | |
| | | weight | | | |
| Example | Synthesis | 100 | Ballast 1 | 20 parts by | — |
| 37 | Example 7 | parts by | | weight | |
| | | weight | | | |
| Example | Synthesis | 100 | Ballast 1 | 20 parts by | — |
| 38 | Example 8 | parts by | | weight | |
| | | weight | | | |
| Example | Synthesis | 100 | Ballast 1 | 20 parts by | — |
| 39 | Example 9 | parts by | | weight | |
| | | weight | | | |
| Example | Synthesis | 100 | Ballast 1 | 20 parts by | — |
| 40 | Example 10 | parts by | | weight | |
| | | weight | | | |
| Example | Synthesis | 100 | Ballast 1 | 20 parts by | — |
| 41 | Example 11 | parts by | | weight | |
| | | weight | | | |
| Example | Synthesis | 100 | Ballast 1 | 20 parts by | — |
| 42 | Example 12 | parts by | | weight | |
| | | weight | | | |
| Example | Synthesis | 100 | Ballast 2 | 20 parts by | — |
| 43 | Example 1 | parts by | | weight | |
| | | weight | | | |
| Example | Synthesis | 100 | Ballast 2 | 20 parts by | — |
| 44 | Example 2 | parts by | | weight | |
| | | weight | | | |
| Example | Synthesis | 100 | Ballast 2 | 20 parts by | — |
| 45 | Example 3 | parts by | | weight | |
| | | weight | | | |
| Example | Synthesis | 100 | Ballast 2 | 20 parts by | — |
| 46 | Example 4 | parts by | | weight | |
| | | weight | | | |
| Example | Synthesis | 100 | Ballast 2 | 20 parts by | — |
| 47 | Example 5 | parts by | | weight | |
| | | weight | | | |
| Example | Synthesis | 100 | Ballast 2 | 20 parts by | — |
| 48 | Example 6 | parts by | | weight | |
| | | weight | | | |
| Example | Synthesis | 100 | Ballast 2 | 20 parts by | — |
| 49 | Example 7 | parts by | | weight | |
| | | weight | | | |
| Example | Synthesis | 100 | Ballast 2 | 20 parts by | — |
| 50 | Example 8 | parts by | | weight | |
| | | weight | | | |
| Example | Synthesis | 100 | Ballast 2 | 20 parts by | — |
| 51 | Example 9 | parts by | | weight | |
| | | weight | | | |
| Example | Synthesis | 100 | Ballast 2 | 20 parts by | — |
| 52 | Example 10 | parts by | | weight | |
| | | weight | | | |
| Example | Synthesis | 100 | Ballast 2 | 20 parts by | — |
| 53 | Example 11 | parts by | | weight | |
| | | weight | | | |
| Example | Synthesis | 100 | Ballast 2 | 20 parts by | — |
| 54 | Example 12 | parts by | | weight | |
| | | weight | | | |
| Example | Synthesis | 100 | Ballast 3 | 20 parts by | — |
| 55 | Example 1 | parts by | | weight | |
| | | weight | | | |
| Example | Synthesis | 100 | Ballast 3 | 20 parts by | — |
| 56 | Example 2 | parts by | | weight | |
| | | weight | | | |
| Example | Synthesis | 100 | Ballast 3 | 20 parts by | — |
| 57 | Example 3 | parts by | | weight | |
| | | weight | | | |
| Example | Synthesis | 100 | Ballast 3 | 20 parts by | — |
| 58 | Example 4 | parts by | | weight | |
| | | weight | | | |
| Example | Synthesis | 100 | Ballast 3 | 20 parts by | — |
| 59 | Example 5 | parts by | | weight | |
| | | weight | | | |
| Example | Synthesis | 100 | Ballast 3 | 20 parts by | — |
| 60 | Example 6 | parts by | | weight | |
| | | weight | | | |
| Example | Synthesis | 100 | Ballast 3 | 20 parts by | — |
| 61 | Example 7 | parts by | | weight | |
| | | weight | | | |
| Example | Synthesis | 100 | Ballast 3 | 20 parts by | — |
| 62 | Example 8 | parts by | | weight | |
| | | weight | | | |
| Example | Synthesis | 100 | Ballast 3 | 20 parts by | — |
| 63 | Example 9 | parts by | | weight | |
| | | weight | | | |
| Example | Synthesis | 100 | Ballast 3 | 20 parts by | — |
| 64 | Example 10 | parts by | | weight | |
| | | weight | | | |
| Example | Synthesis | 100 | Ballast 3 | 20 parts by | — |
| 65 | Example 11 | parts by | | weight | |
| | | weight | | | |
| Example | Synthesis | 100 | Ballast 3 | 20 parts by | — |
| 66 | Example 12 | parts by | | weight | |
| | | weight | | | |
| Example | Synthesis | 100 | Ballast 4 | 20 parts by | — |
| 67 | Example 1 | parts by | | weight | |
| | | weight | | | |
| Example | Synthesis | 100 | Ballast 4 | 20 parts by | — |
| 68 | Example 2 | parts by | | weight | |
| | | weight | | | |
| Example | Synthesis | 100 | Ballast 4 | 20 parts by | — |
| 69 | Example 3 | parts by | | weight | |
| | | weight | | | |
| Example | Synthesis | 100 | Ballast 4 | 20 parts by | — |
| 70 | Example 4 | parts by | | weight | |
| | | weight | | | |
| Example | Synthesis | 100 | Ballast 4 | 20 parts by | — |
| 71 | Example 5 | parts by | | weight | |
| | | weight | | | |
| Example | Synthesis | 100 | Ballast 4 | 20 parts by | — |
| 72 | Example 6 | parts by | | weight | |
| | | weight | | | |
| Example | Synthesis | 100 | Ballast 4 | 20 parts by | — |
| 73 | Example 7 | parts by | | weight | |
| | | weight | | | |
| Example | Synthesis | 100 | Ballast 4 | 20 parts by | — |
| 74 | Example 8 | parts by | | weight | |
| | | weight | | | |
| Example | Synthesis | 100 | Ballast 4 | 20 parts by | — |
| 75 | Example 9 | parts by | | weight | |
| | | weight | | | |
| Example | Synthesis | 100 | Ballast 4 | 20 parts by | — |
| 76 | Example 10 | parts by | | weight | |
| | | weight | | | |
| Example | Synthesis | 100 | Ballast 4 | 20 parts by | — |
| 77 | Example 11 | parts by | | weight | |
| | | weight | | | |
| Example | Synthesis | 100 | Ballast 4 | 20 parts by | — |
| 78 | Example 12 | parts by | | weight | |
| | | weight | | | |
| Example | Synthesis | 100 | Ballast 5 | 20 parts by | — |
| 79 | Example 1 | parts by | | weight | |
| | | weight | | | |
| Example | Synthesis | 100 | Ballast 5 | 20 parts by | — |
| 80 | Example 2 | parts by | | weight | |
| | | weight | | | |
| Example | Synthesis | 100 | Ballast 5 | 20 parts by | — |
| 81 | Example 3 | parts by | | weight | |
| | | weight | | | |
| Example | Synthesis | 100 | Ballast 5 | 20 parts by | — |
| 82 | Example 4 | parts by | | weight | |
| | | weight | | | |
| Example | Synthesis | 100 | Ballast 5 | 20 parts by | — |
| 83 | Example 5 | parts by | | weight | |
| | | weight | | | |
| Example | Synthesis | 100 | Ballast 5 | 20 parts by | — |
| 84 | Example 6 | parts by | | weight | |
| | | weight | | | |
| Example | Synthesis | 100 | Ballast 5 | 20 parts by | — |
| 85 | Example 7 | parts by | | weight | |
| | | weight | | | |
| Example | Synthesis | 100 | Ballast 5 | 20 parts by | — |
| 86 | Example 8 | parts by | | weight | |
| | | weight | | | |
| Example | Synthesis | 100 | Ballast 5 | 20 parts by | — |
| 87 | Example 9 | parts by | | weight | |
| | | weight | | | |
| Example | Synthesis | 100 | Ballast 5 | 20 parts by | — |
| 88 | Example 10 | parts by | | weight | |
| | | weight | | | |
| Example | Synthesis | 100 | Ballast 5 | 20 parts by | — |
| 89 | Example 11 | parts by | | weight | |
| | | weight | | | |
| Example | Synthesis | 100 | Ballast 5 | 20 parts by | — |
| 90 | Example 12 | parts by | | weight | |
| | | weight | | | |
| Example | Synthesis | 100 | Ballast 6 | 20 parts by | — |
| 91 | Example 1 | parts by | | weight | |
| | | weight | | | |
| Example | Synthesis | 100 | Ballast 6 | 20 parts by | — |
| 92 | Example 2 | parts by | | weight | |
| | | weight | | | |
| Example | Synthesis | 100 | Ballast 6 | 20 parts by | — |
| 93 | Example 3 | parts by | | weight | |
| | | weight | | | |
| Example | Synthesis | 100 | Ballast 6 | 20 parts by | — |
| 94 | Example 4 | parts by | | weight | |
| | | weight | | | |
| Example | Synthesis | 100 | Ballast 6 | 20 parts by | — |
| 95 | Example 5 | parts by | | weight | |
| | | weight | | | |
| Example | Synthesis | 100 | Ballast 6 | 20 parts by | — |
| 96 | Example 6 | parts by | | weight | |
| | | weight | | | |
| Example | Synthesis | 100 | Ballast 6 | 20 parts by | — |
| 97 | Example 7 | parts by | | weight | |
| | | weight | | | |
| Example | Synthesis | 100 | Ballast 6 | 20 parts by | — |
| 98 | Example 8 | parts by | | weight | |
| | | weight | | | |
| Example | Synthesis | 100 | Ballast 6 | 20 parts by | — |
| 99 | Example 9 | parts by | | weight | |
| | | weight | | | |
| Example | Synthesis | 100 | Ballast 6 | 20 parts by | — |
| 100 | Example 10 | parts by | | weight | |
| | | weight | | | |
| Example | Synthesis | 100 | Ballast 6 | 20 parts by | — |
| 101 | Example 11 | parts by | | weight | |
| | | weight | | | |
| Example | Synthesis | 100 | Ballast 6 | 20 parts by | — |
| 102 | Example 12 | parts by | | weight | |
| | | weight | | | |

TABLE 8

| | | | Photoactive compound | | Colored |
|---|---|---|---|---|---|
| | Alkali-soluble resin | | (colored PAC) | | additive |
| | Structure | Content | Structure | Content | Content |
| Example | Synthesis | 100 | Ballast 1 | 20 parts by | — |
| 103 | Example 31 | parts by | | weight | |
| | | weight | | | |
| Example | Synthesis | 100 | Ballast 1 | 20 parts by | — |
| 104 | Example 32 | parts by | | weight | |
| | | weight | | | |
| Example | Synthesis | 100 | Ballast 1 | 20 parts by | — |
| 105 | Example 33 | parts by | | weight | |
| | | weight | | | |
| Example | Synthesis | 100 | Ballast 1 | 20 parts by | — |
| 106 | Example 34 | parts by | | weight | |
| | | weight | | | |
| Example | Synthesis | 100 | Ballast 1 | 20 parts by | — |
| 107 | Example 35 | parts by | | weight | |
| | | weight | | | |
| Example | Synthesis | 100 | Ballast 1 | 20 parts by | — |
| 108 | Example 36 | parts by | | weight | |
| | | weight | | | |
| Example | Synthesis | 100 | Ballast 2 | 20 parts by | — |
| 109 | Example 31 | parts by | | weight | |
| | | weight | | | |
| Example | Synthesis | 100 | Ballast 2 | 20 parts by | — |
| 110 | Example 32 | parts by | | weight | |
| | | weight | | | |
| Example | Synthesis | 100 | Ballast 2 | 20 parts by | — |
| 111 | Example 33 | parts by | | weight | |
| | | weight | | | |
| Example | Synthesis | 100 | Ballast 2 | 20 parts by | — |
| 112 | Example 34 | parts by | | weight | |
| | | weight | | | |
| Example | Synthesis | 100 | Ballast 2 | 20 parts by | — |
| 113 | Example 35 | parts by | | weight | |
| | | weight | | | |
| Example | Synthesis | 100 | Ballast 2 | 20 parts by | — |
| 114 | Example 36 | parts by | | weight | |
| | | weight | | | |
| Example | Synthesis | 100 | Ballast 3 | 20 parts by | — |
| 115 | Example 31 | parts by | | weight | |
| | | weight | | | |
| Example | Synthesis | 100 | Ballast 3 | 20 parts by | — |
| 116 | Example 32 | parts by | | weight | |
| | | weight | | | |
| Example | Synthesis | 100 | Ballast 3 | 20 parts by | — |
| 117 | Example 33 | parts by | | weight | |
| | | weight | | | |
| Example | Synthesis | 100 | Ballast 3 | 20 parts by | — |
| 118 | Example 34 | parts by | | weight | |
| | | weight | | | |
| Example | Synthesis | 100 | Ballast 3 | 20 parts by | — |
| 119 | Example 35 | parts by | | weight | |
| | | weight | | | |
| Example | Synthesis | 100 | Ballast 3 | 20 parts by | — |
| 120 | Example 36 | parts by | | weight | |
| | | weight | | | |
| Example | Synthesis | 100 | Ballast 4 | 20 parts by | — |
| 121 | Example 31 | parts by | | weight | |
| | | weight | | | |
| Example | Synthesis | 100 | Ballast 4 | 20 parts by | — |
| 122 | Example 32 | parts by | | weight | |
| | | weight | | | |
| Example | Synthesis | 100 | Ballast 4 | 20 parts by | — |
| 123 | Example 33 | parts by | | weight | |
| | | weight | | | |
| Example | Synthesis | 100 | Ballast 4 | 20 parts by | — |
| 124 | Example 34 | parts by | | weight | |
| | | weight | | | |
| Example | Synthesis | 100 | Ballast 4 | 20 parts by | — |
| 125 | Example 35 | parts by | | weight | |
| | | weight | | | |
| Example | Synthesis | 100 | Ballast 4 | 20 parts by | — |
| 126 | Example 36 | parts by | | weight | |
| | | weight | | | |
| Example | Synthesis | 100 | Ballast 5 | 20 parts by | — |
| 127 | Example 31 | parts by | | weight | |
| | | weight | | | |
| Example | Synthesis | 100 | Ballast 5 | 20 parts by | — |
| 128 | Example 32 | parts by | | weight | |
| | | weight | | | |
| Example | Synthesis | 100 | Ballast 5 | 20 parts by | — |
| 129 | Example 33 | parts by | | weight | |
| | | weight | | | |
| Example | Synthesis | 100 | Ballast 5 | 20 parts by | — |
| 130 | Example 34 | parts by | | weight | |
| | | weight | | | |
| Example | Synthesis | 100 | Ballast 5 | 20 parts by | — |
| 131 | Example 35 | parts by | | weight | |
| | | weight | | | |
| Example | Synthesis | 100 | Ballast 5 | 20 parts by | — |
| 132 | Example 36 | parts by | | weight | |
| | | weight | | | |
| Example | Synthesis | 100 | Ballast 6 | 20 parts by | — |
| 133 | Example 31 | parts by | | weight | |
| | | weight | | | |
| Example | Synthesis | 100 | Ballast 6 | 20 parts | — |
| 134 | Example 32 | parts by | | by | |
| | | weight | | weight | |
| Example | Synthesis | 100 | Ballast 6 | 20 parts by | — |
| 135 | Example 33 | parts by | | weight | |
| | | weight | | | |
| Example | Synthesis | 100 | Ballast 6 | 20 parts by | — |
| 136 | Example 34 | parts by | | weight | |
| | | weight | | | |
| Example | Synthesis | 100 | Ballast 6 | 20 parts by | — |
| 137 | Example 35 | parts by | | weight | |
| | | weight | | | |
| Example | Synthesis | 100 | Ballast 6 | 20 parts by | — |
| 138 | Example 36 | parts by | | weight | |
| | | weight | | | |

TABLE 9

| | | | | | | Degree of |
|---|---|---|---|---|---|---|
| | | | | | | sulfonic |
| | | | Photoactive compound | | Colored | acid |
| | Alkali-soluble resin | | (colored PAC) | | additive | esterification |
| | Structure | Content | Structure | Content | Content | (%) |
| Example 139 | Synthesis | 100 parts by | Ballast 7 | 20 parts by | — | 1.2 |
| | Example 1 | weight | | weight | | |
| Example 140 | Synthesis | 100 parts by | Ballast 7 | 20 parts by | — | 3.0 |
| | Example 1 | weight | | weight | | |
| Example 141 | Synthesis | 100 parts by | Ballast 7 | 20 parts by | — | 1.0 |
| | Example 1 | weight | | weight | | |
| Example 142 | Synthesis | 100 parts by | Ballast 7 | 20 parts by | — | 3.3 |
| | Example 1 | weight | | weight | | |
| Example 143 | Synthesis | 100 parts by | Ballast 7 | 20 parts by | — | 2.0 |
| | Example 37 | weight | | weight | | |
| Example 144 | Synthesis | 100 parts by | Ballast 7 | 20 parts by | — | 2.0 |
| | Example 38 | weight | | weight | | |
| Example 145 | Synthesis | 100 parts by | Ballast 7 | 20 parts by | — | 2.0 |
| | Example 39 | weight | | weight | | |
| Example 146 | Synthesis | 100 parts by | Ballast 7 | 20 parts by | — | 2.0 |
| | Example 40 | weight | | weight | | |
| Example 147 | Synthesis | 100 parts by | Ballast 7 | 20 parts by | — | 2.0 |
| | Example 41 | weight | | weight | | |
| Example 148 | Synthesis | 100 parts by | Ballast 7 | 20 parts by | — | 2.0 |
| | Example 42 | weight | | weight | | |
| Example 149 | Synthesis | 100 parts by | Ballast 7 | 5 parts by | — | 2.0 |
| | Example 1 | weight | | weight | | |
| Example 150 | Synthesis | 100 parts by | Ballast 7 | 10 parts by | — | 2.0 |
| | Example 1 | weight | | weight | | |
| Example 151 | Synthesis | 100 parts by | Ballast 7 | 30 parts by | — | 2.0 |
| | Example 1 | weight | | weight | | |
| Example 152 | Synthesis | 100 parts by | Ballast 7 | 40 parts by | — | 2.0 |
| | Example 1 | weight | | weight | | |
| Example 153 | Synthesis | 100 parts by | Ballast 7 | 45 parts by | — | 2.0 |
| | Example 1 | weight | | weight | | |
| Example 154 | Synthesis | 100 parts by | Ballast 7 | 1 part by | — | 2.0 |
| | Example 1 | weight | | weight | | |

Meanwhile, compounds represented by Formulas D-1 and D-2 below were prepared as colored additives 1 and 2 in Table 10 below, respectively.

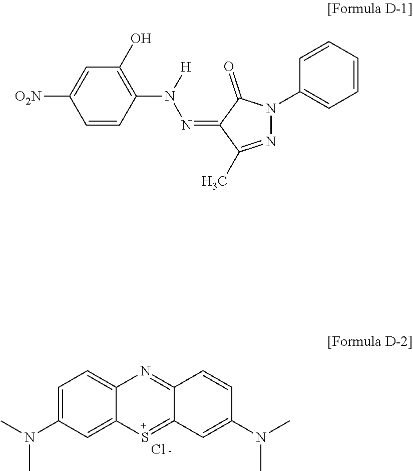

TABLE 10

| | | | Photoactive compound | | | |
|---|---|---|---|---|---|---|
| | Alkali-soluble resin | | (transparent PAC) | | Colored additive | |
| | Structure | Content | Structure | Content | Structure | Content |
| Example | Comparative | 100 parts by | TPPA | 20 parts by | — | — |
| 155 | Synthesis | weight | | weight | | |
| | Example 2 | | | | | |
| Example | Comparative | 100 parts by | TPPA | 20 parts by | — | — |
| 156 | Synthesis | weight | | weight | | |
| | Example 3 | | | | | |
| Example | Comparative | 100 parts by | TPPA | 20 parts by | — | — |
| 157 | Synthesis | weight | | weight | | |
| | Example 5 | | | | | |
| Example | Comparative | 100 parts by | TPPA | 20 parts by | — | — |
| 158 | Synthesis | weight | | weight | | |
| | Example 6 | | | | | |
| Comparative | Comparative | 100 parts by | TPPA | 20 parts by | D-1 | 20 |
| Example 7 | Synthesis | weight | | weight | | |
| | Example 1 | | | | | |
| Comparative | Comparative | 100 parts by | TPPA | 20 parts by | D-1 | 20 |
| Example 8 | Synthesis | weight | | weight | | |
| | Example 2 | | | | | |
| Comparative | Comparative | 100 parts by | TPPA | 20 parts by | D-1 | 20 |
| Example 9 | Synthesis | weight | | weight | | |
| | Example 3 | | | | | |
| Comparative | Comparative | 100 parts by | TPPA | 20 parts by | D-1 | 20 |
| Example | Synthesis | weight | | weight | | |
| 10 | Example 4 | | | | | |
| Comparative | Comparative | 100 parts by | TPPA | 20 parts by | D-1 | 20 |
| Example | Synthesis | weight | | weight | | |
| 11 | Example 5 | | | | | |
| Comparative | Comparative | 100 parts by | TPPA | 20 parts by | D-1 | 20 |
| Example | Synthesis | weight | | weight | | |
| 12 | Example 6 | | | | | |
| Comparative | Comparative | 100 parts by | TPPA | 20 parts by | D-2 | 20 |
| Example | Synthesis | weight | | weight | | |
| 13 | Example 1 | | | | | |
| Comparative | Comparative | 100 parts by | TPPA | 20 parts by | D-2 | 20 |
| Example | Synthesis | weight | | weight | | |
| 14 | Example 2 | | | | | |
| Comparative | Comparative | 100 parts by | TPPA | 20 parts by | D-2 | 20 |
| Example | Synthesis | weight | | weight | | |
| 15 | Example 3 | | | | | |
| Comparative | Comparative | 100 parts by | TPPA | 20 parts by | D-2 | 20 |
| Example | Synthesis | weight | | weight | | |
| 16 | Example 4 | | | | | |
| Comparative | Comparative | 100 parts by | TPPA | 20 parts by | D-2 | 20 |
| Example | Synthesis | weight | | weight | | |
| 17 | Example 5 | | | | | |
| Comparative | Comparative | 100 parts by | TPPA | 20 parts by | D-2 | 20 |
| Example | Synthesis | weight | | weight | | |
| 18 | Example 6 | | | | | |
| Example | Comparative | 100 parts by | Ballast 1 | 9 parts by | — | — |
| 159 | Synthesis | weight | | weight | | |
| | Example 7 | | | | | |
| Example | Comparative | 100 parts by | TPPA | 20 parts by - | — | — |
| 160 | Synthesis | weight | | weight | | |
| | Example 8 | | | | | |
| Example | Synthesis | 100 parts by | TPPA | 20 parts by | — | — |
| 161 | Example 43 | weight | | weight | | |

### Experimental Example: Evaluation of Photosensitive Resin Composition and Insulating Film

After the photosensitive resin composition according to each of the Preparation Examples was applied onto an ITO substrate using a slit coater, it was subjected to a vacuum drying (VCD) process up to a pressure of 66 Pa and prebaked on a hot plate at 120° C. for 2 minutes to form a cured film having a thickness of 1.5 μm.

### 1) Sensitivity

Using a predetermined pattern mask, the cured film formed as described above was irradiated with UV light having an intensity of 20 mW/cm² in the broadband at a dose corresponding to a 2.5 μm contact hole CD. Next, the cured film was developed with a 2.38 wt % aqueous solution of tetramethyl ammonium hydroxide at 23° C. for 1 minute, and then rinsed with ultrapure water for 1 minute. Then, the film was cured in an oven at 250° C. for 60 minutes to obtain a patterned film (insulating film) having a thickness of 2.0 μm.

Sensitivity was indicated as follows. ⊚: 80 mJ or less; ◯: more than 80 mJ and 100 mJ or less; Δ: more than 100 mJ and 120 mJ or less; and X: more than 120 mJ.

### 2) Film Retention Rate

The change in thickness of the film formed during the sensitivity measurement in 1) above was measured.

Film retention rate=(thickness after curing/thickness of prebaking). The film retention rate was indicated as follows. ⊚: 65% or more; 60% or more; Δ: 50% or more and less than 60%, and X: less than 50%.

### 3) Transmittance

To evaluate transmittance, the transmittance (400 to 500 nm) of the patterned film formed during the sensitivity measurement was measured using a spectrophotometer. The transmittance was indicated as follows. ⊚: less than 10%, ◯: more than 10% and less than 20%, Δ: 20% or more and 50% or less, and X: more than 50%.

### 4) Adhesion

The patterned film was formed in the same manner as the sensitivity measurement in 1) above, and the adhesion thereof was comparatively evaluated based on the minimum CD of the attached dot pattern. The adhesion was indicated as follows. ◯: the adhesion is secured when the minimum CD of the dot pattern is 5 μm or more and less than 10 μm; Δ: the adhesion is secured when the minimum CD of the dot pattern is 10 μm or more and less than 15 μm; and X: the adhesion is secured or not secured when the minimum CD of the dot pattern is 15 μm or more.

### 5) Chemical Resistance

The cured film formed on the substrate was immersed in methylpyrrolidone (NMP) at 60° C. for 120 seconds, and the change in the thickness of the cured film between before and after immersion was measured. Chemical resistance was indicated as follows. ◯: the change in the thickness is less than 300 Å; Δ: the change in the thickness is 300 Å or more and less than 600 Å, and X; and the change in the thickness is 600 Å or more.

### 6) Heat Resistance

Heat resistance was measured using TGA. After sampling the patterned film formed during the sensitivity measurement in 1) above, the sample was heated from room temperature to 900° C. at a rate of 10° C. per minute using TGA. Heat resistance was indicated as follows. ◯: the 5 wt % loss temperature is higher than 300° C.; Δ: the 5 wt % loss temperature is 280 to 300° C., and X: the 5 wt % loss temperature is lower than 280° C.

### 7) Hygroscopicity

The patterned film formed during the sensitivity measurement in 1) above was purified in a constant temperature and constant humidity oven at 85° C. and 85% RH for 240 hours, and then the hygroscopicity was evaluated based on the change in film thickness between before and after being placed in the oven. The hygroscopicity was indicated as follows. ◯: the change in the film thickness is less than 300 Å; Δ: the change in the film thickness is 300 Å or more to less than 600 Å; and X: the change in the film thickness is 600 Å or more.

### 8) OLED Operation Reliability

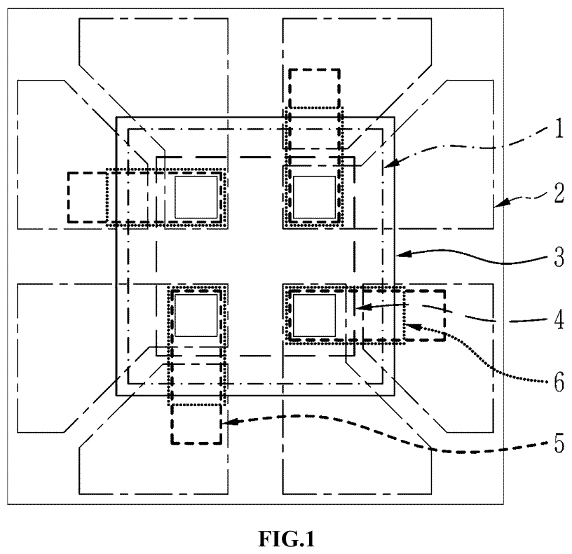

FIG. 1 illustrates a display device according to one embodiment of the present disclosure. Referring to FIG. 1, the display device according to one embodiment of the present disclosure may include a via 1, an anode electrode 2, a pixel define layer (PDL) 3, an EL 4, a cathode electrode 5, and a capping layer (CPL) 6.

A patterned film was formed on a substrate shown in FIG. 1 in the same manner as in the sensitivity measurement in 1) above, and the EL 4 was deposited thereon. Mg/Ag was deposited as the cathode electrode 5 thereon, and an encapsulation process was performed. The time (T₉₇) for a 3% luminance drop in the “on” state of the OLED element at 85° C. and 85% RH was evaluated. Operation reliability was indicated as follows. ◯: the time is 1,000 or more; Δ: the time is 700 to less than 1,000 hours; and X: the time is less than 700 hours.

TABLE 11

| | | Film | Transmittance | | | | | |
|---|---|---|---|---|---|---|---|---|
| | | retention | (low | | Chemical | Heat | | Operation |
| | Sensitivity | rate | transmittance) | Adhesion | resistance | resistance | Hygroscopicity | reliability |
| Example | ⊚ | ◯ | ◯ | ◯ | ◯ | ◯ | ◯ | ◯ |
| 1 | | | | | | | | |
| Example | ⊚ | ◯ | ◯ | ◯ | ◯ | ◯ | ◯ | ◯ |
| 2 | | | | | | | | |
| Example | ⊚ | ◯ | ◯ | ◯ | ◯ | ◯ | ◯ | ◯ |
| 3 | | | | | | | | |
| Example | ⊚ | ◯ | ◯ | ◯ | ◯ | ◯ | ◯ | ◯ |
| 4 | | | | | | | | |
| Example | ⊚ | ◯ | ◯ | ◯ | ◯ | ◯ | ◯ | ◯ |
| 5 | | | | | | | | |
| Example | ⊚ | ◯ | ◯ | ◯ | ◯ | ◯ | ◯ | ◯ |
| 6 | | | | | | | | |
| Example | ⊚ | ◯ | ◯ | ◯ | ◯ | ◯ | ◯ | ◯ |
| 7 | | | | | | | | |
| Example | ⊚ | ◯ | ◯ | ◯ | ◯ | ◯ | ◯ | ◯ |
| 8 | | | | | | | | |
| Example | ⊚ | ◯ | ◯ | ◯ | ◯ | ◯ | ◯ | ◯ |
| 9 | | | | | | | | |
| Example | ⊚ | ◯ | ◯ | ◯ | ◯ | ◯ | ◯ | ◯ |
| 10 | | | | | | | | |
| Example | ⊚ | ◯ | ◯ | ◯ | ◯ | ◯ | ◯ | ◯ |
| 11 | | | | | | | | |
| Example | ⊚ | ◯ | ◯ | ◯ | ◯ | ◯ | ◯ | ◯ |
| 12 | | | | | | | | |
| Example | ◯ | ◯ | ⊚ | ◯ | ◯ | ◯ | ◯ | ◯ |
| 13 | | | | | | | | |
| Example | ◯ | ◯ | ⊚ | ◯ | ◯ | ◯ | ◯ | ◯ |
| 14 | | | | | | | | |
| Example | ◯ | ◯ | ⊚ | ◯ | ◯ | ◯ | ◯ | ◯ |
| 15 | | | | | | | | |
| Example | ◯ | ◯ | ⊚ | ◯ | ◯ | ◯ | ◯ | ◯ |
| 16 | | | | | | | | |
| Example | ◯ | ◯ | ⊚ | ◯ | ◯ | ◯ | ◯ | ◯ |
| 17 | | | | | | | | |
| Example | ◯ | ◯ | ⊚ | ◯ | ◯ | ◯ | ◯ | ◯ |
| 18 | | | | | | | | |
| Example | ◯ | ◯ | ⊚ | ◯ | ◯ | ◯ | ◯ | ◯ |
| 19 | | | | | | | | |
| Example | ◯ | ◯ | ⊚ | ◯ | ◯ | ◯ | ◯ | ◯ |
| 20 | | | | | | | | |
| Example | ◯ | ◯ | ⊚ | ◯ | ◯ | ◯ | ◯ | ◯ |
| 21 | | | | | | | | |
| Example | ◯ | ◯ | ⊚ | ◯ | ◯ | ◯ | ◯ | ◯ |
| 22 | | | | | | | | |
| Example | ◯ | ◯ | ⊚ | ◯ | ◯ | ◯ | ◯ | ◯ |
| 23 | | | | | | | | |
| Example | ◯ | ◯ | ⊚ | ◯ | ◯ | ◯ | ◯ | ◯ |
| 24 | | | | | | | | |
| Example | ◯ | ◯ | ⊚ | ◯ | ◯ | ◯ | ◯ | ◯ |
| 25 | | | | | | | | |
| Example | ◯ | ◯ | ⊚ | ◯ | ◯ | ◯ | ◯ | ◯ |
| 26 | | | | | | | | |
| Example | ◯ | ◯ | ⊚ | ◯ | ◯ | ◯ | ◯ | ◯ |
| 27 | | | | | | | | |
| Example | ◯ | ◯ | ⊚ | ◯ | ◯ | ◯ | ◯ | ◯ |
| 28 | | | | | | | | |
| Example | ◯ | ◯ | ⊚ | ◯ | ◯ | ◯ | ◯ | ◯ |
| 29 | | | | | | | | |
| Example | ◯ | ◯ | ⊚ | ◯ | ◯ | ◯ | ◯ | ◯ |
| 30 | | | | | | | | |

TABLE 12

| | | Film | Transmittance | | | | | |
|---|---|---|---|---|---|---|---|---|
| | | retention | (low | | Chemical | Heat | | Operation |
| | Sensitivity | rate | transmittance) | Adhesion | resistance | resistance | Hygroscopicity | reliability |
| Example | ◯ | ⊚ | ⊚ | ◯ | ◯ | ◯ | ◯ | ◯ |
| 31 | | | | | | | | |
| Example | ◯ | ⊚ | ⊚ | ◯ | ◯ | ◯ | ◯ | ◯ |
| 32 | | | | | | | | |
| Example | ◯ | ⊚ | ⊚ | ◯ | ◯ | ◯ | ◯ | ◯ |
| 33 | | | | | | | | |
| Example | ◯ | ⊚ | ⊚ | ◯ | ◯ | ◯ | ◯ | ◯ |
| 34 | | | | | | | | |
| Example | ◯ | ⊚ | ⊚ | ◯ | ◯ | ◯ | ◯ | ◯ |
| 35 | | | | | | | | |
| Example | ◯ | ⊚ | ⊚ | ◯ | ◯ | ◯ | ◯ | ◯ |
| 36 | | | | | | | | |
| Example | ◯ | ⊚ | ⊚ | ◯ | ◯ | ◯ | ◯ | ◯ |
| 37 | | | | | | | | |
| Example | ◯ | ⊚ | ⊚ | ◯ | ◯ | ◯ | ◯ | ◯ |
| 38 | | | | | | | | |
| Example | ◯ | ⊚ | ⊚ | ◯ | ◯ | ◯ | ◯ | ◯ |
| 39 | | | | | | | | |
| Example | ◯ | ⊚ | ⊚ | ◯ | ◯ | ◯ | ◯ | ◯ |
| 40 | | | | | | | | |
| Example | ◯ | ⊚ | ⊚ | ◯ | ◯ | ◯ | ◯ | ◯ |
| 41 | | | | | | | | |
| Example | ◯ | ⊚ | ⊚ | ◯ | ◯ | ◯ | ◯ | ◯ |
| 42 | | | | | | | | |
| Example | ◯ | ⊚ | ⊚ | ◯ | ◯ | ◯ | ◯ | ◯ |
| 43 | | | | | | | | |
| Example | ◯ | ⊚ | ⊚ | ◯ | ◯ | ◯ | ◯ | ◯ |
| 44 | | | | | | | | |
| Example | ◯ | ⊚ | ⊚ | ◯ | ◯ | ◯ | ◯ | ◯ |
| 45 | | | | | | | | |
| Example | ◯ | ⊚ | ⊚ | ◯ | ◯ | ◯ | ◯ | ◯ |
| 46 | | | | | | | | |
| Example | ◯ | ⊚ | ⊚ | ◯ | ◯ | ◯ | ◯ | ◯ |
| 47 | | | | | | | | |
| Example | ◯ | ⊚ | ⊚ | ◯ | ◯ | ◯ | ◯ | ◯ |
| 48 | | | | | | | | |
| Example | ◯ | ⊚ | ⊚ | ◯ | ◯ | ◯ | ◯ | ◯ |
| 49 | | | | | | | | |
| Example | ◯ | ⊚ | ⊚ | ◯ | ◯ | ◯ | ◯ | ◯ |
| 50 | | | | | | | | |
| Example | ◯ | ⊚ | ⊚ | ◯ | ◯ | ◯ | ◯ | ◯ |
| 51 | | | | | | | | |
| Example | ◯ | ⊚ | ⊚ | ◯ | ◯ | ◯ | ◯ | ◯ |
| 52 | | | | | | | | |
| Example | ◯ | ⊚ | ⊚ | ◯ | ◯ | ◯ | ◯ | ◯ |
| 53 | | | | | | | | |
| Example | ◯ | ⊚ | ⊚ | ◯ | ◯ | ◯ | ◯ | ◯ |
| 54 | | | | | | | | |
| Example | ◯ | ⊚ | ⊚ | ◯ | ◯ | ◯ | ◯ | ◯ |
| 55 | | | | | | | | |
| Example | ◯ | ⊚ | ⊚ | ◯ | ◯ | ◯ | ◯ | ◯ |
| 56 | | | | | | | | |
| Example | ◯ | ⊚ | ⊚ | ◯ | ◯ | ◯ | ◯ | ◯ |
| 57 | | | | | | | | |
| Example | ◯ | ⊚ | ⊚ | ◯ | ◯ | ◯ | ◯ | ◯ |
| 58 | | | | | | | | |
| Example | ◯ | ⊚ | ⊚ | ◯ | ◯ | ◯ | ◯ | ◯ |
| 59 | | | | | | | | |
| Example | ◯ | ⊚ | ⊚ | ◯ | ◯ | ◯ | ◯ | ◯ |
| 60 | | | | | | | | |
| Example | ◯ | ⊚ | ⊚ | ◯ | ◯ | ◯ | ◯ | ◯ |
| 61 | | | | | | | | |
| Example | ◯ | ⊚ | ⊚ | ◯ | ◯ | ◯ | ◯ | ◯ |
| 62 | | | | | | | | |
| Example | ◯ | ⊚ | ⊚ | ◯ | ◯ | ◯ | ◯ | ◯ |
| 63 | | | | | | | | |
| Example | ◯ | ⊚ | ⊚ | ◯ | ◯ | ◯ | ◯ | ◯ |
| 64 | | | | | | | | |
| Example | ◯ | ⊚ | ⊚ | ◯ | ◯ | ◯ | ◯ | ◯ |
| 65 | | | | | | | | |
| Example | ◯ | ⊚ | ⊚ | ◯ | ◯ | ◯ | ◯ | ◯ |
| 66 | | | | | | | | |
| Example | ◯ | ⊚ | ⊚ | ◯ | ◯ | ◯ | ◯ | ◯ |
| 67 | | | | | | | | |
| Example | ◯ | ⊚ | ⊚ | ◯ | ◯ | ◯ | ◯ | ◯ |
| 68 | | | | | | | | |
| Example | ◯ | ⊚ | ⊚ | ◯ | ◯ | ◯ | ◯ | ◯ |
| 69 | | | | | | | | |
| Example | ◯ | ⊚ | ⊚ | ◯ | ◯ | ◯ | ◯ | ◯ |
| 70 | | | | | | | | |
| Example | ◯ | ⊚ | ⊚ | ◯ | ◯ | ◯ | ◯ | ◯ |
| 71 | | | | | | | | |
| Example | ◯ | ⊚ | ⊚ | ◯ | ◯ | ◯ | ◯ | ◯ |
| 72 | | | | | | | | |
| Example | ◯ | ⊚ | ⊚ | ◯ | ◯ | ◯ | ◯ | ◯ |
| 73 | | | | | | | | |
| Example | ◯ | ⊚ | ⊚ | ◯ | ◯ | ◯ | ◯ | ◯ |
| 74 | | | | | | | | |
| Example | ◯ | ⊚ | ⊚ | ◯ | ◯ | ◯ | ◯ | ◯ |
| 75 | | | | | | | | |
| Example | ◯ | ⊚ | ⊚ | ◯ | ◯ | ◯ | ◯ | ◯ |
| 76 | | | | | | | | |
| Example | ◯ | ⊚ | ⊚ | ◯ | ◯ | ◯ | ◯ | ◯ |
| 77 | | | | | | | | |
| Example | ◯ | ⊚ | ⊚ | ◯ | ◯ | ◯ | ◯ | ◯ |
| 78 | | | | | | | | |
| Example | ◯ | ⊚ | ⊚ | ◯ | ◯ | ◯ | ◯ | ◯ |
| 79 | | | | | | | | |
| Example | ◯ | ⊚ | ⊚ | ◯ | ◯ | ◯ | ◯ | ◯ |
| 80 | | | | | | | | |
| Example | ◯ | ⊚ | ⊚ | ◯ | ◯ | ◯ | ◯ | ◯ |
| 81 | | | | | | | | |
| Example | ◯ | ⊚ | ⊚ | ◯ | ◯ | ◯ | ◯ | ◯ |
| 82 | | | | | | | | |
| Example | ◯ | ⊚ | ⊚ | ◯ | ◯ | ◯ | ◯ | ◯ |
| 83 | | | | | | | | |
| Example | ◯ | ⊚ | ⊚ | ◯ | ◯ | ◯ | ◯ | ◯ |
| 84 | | | | | | | | |
| Example | ◯ | ⊚ | ⊚ | ◯ | ◯ | ◯ | ◯ | ◯ |
| 85 | | | | | | | | |
| Example | ◯ | ⊚ | ⊚ | ◯ | ◯ | ◯ | ◯ | ◯ |
| 86 | | | | | | | | |
| Example | ◯ | ⊚ | ⊚ | ◯ | ◯ | ◯ | ◯ | ◯ |
| 87 | | | | | | | | |
| Example | ◯ | ⊚ | ⊚ | ◯ | ◯ | ◯ | ◯ | ◯ |
| 88 | | | | | | | | |
| Example | ◯ | ⊚ | ⊚ | ◯ | ◯ | ◯ | ◯ | ◯ |
| 89 | | | | | | | | |
| Example | ◯ | ⊚ | ⊚ | ◯ | ◯ | ◯ | ◯ | ◯ |
| 90 | | | | | | | | |
| Example | ◯ | ⊚ | ⊚ | ◯ | ◯ | ◯ | ◯ | ◯ |
| 91 | | | | | | | | |
| Example | ◯ | ⊚ | ⊚ | ◯ | ◯ | ◯ | ◯ | ◯ |
| 92 | | | | | | | | |
| Example | ◯ | ⊚ | ⊚ | ◯ | ◯ | ◯ | ◯ | ◯ |
| 93 | | | | | | | | |
| Example | ◯ | ⊚ | ⊚ | ◯ | ◯ | ◯ | ◯ | ◯ |
| 94 | | | | | | | | |
| Example | ◯ | ⊚ | ⊚ | ◯ | ◯ | ◯ | ◯ | ◯ |
| 95 | | | | | | | | |
| Example | ◯ | ⊚ | ⊚ | ◯ | ◯ | ◯ | ◯ | ◯ |
| 96 | | | | | | | | |
| Example | ◯ | ⊚ | ⊚ | ◯ | ◯ | ◯ | ◯ | ◯ |
| 97 | | | | | | | | |
| Example | ◯ | ⊚ | ⊚ | ◯ | ◯ | ◯ | ◯ | ◯ |
| 98 | | | | | | | | |
| Example | ◯ | ⊚ | ⊚ | ◯ | ◯ | ◯ | ◯ | ◯ |
| 99 | | | | | | | | |
| Example | ◯ | ⊚ | ⊚ | ◯ | ◯ | ◯ | ◯ | ◯ |
| 100 | | | | | | | | |
| Example | ◯ | ⊚ | ⊚ | ◯ | ◯ | ◯ | ◯ | ◯ |
| 101 | | | | | | | | |
| Example | ◯ | ⊚ | ⊚ | ◯ | ◯ | ◯ | ◯ | ◯ |
| 102 | | | | | | | | |

TABLE 13

| | | Film | Transmittance | | | | | |
|---|---|---|---|---|---|---|---|---|
| | | retention | (low | | Chemical | Heat | | Operation |
| | Sensitivity | rate | transmittance) | Adhesion | resistance | resistance | Hygroscopicity | reliability |
| Example | ⊚ | ⊚ | ◯ | ◯ | ◯ | ◯ | ◯ | ◯ |
| 103 | | | | | | | | |
| Example | ⊚ | ⊚ | ◯ | ◯ | ◯ | ◯ | ◯ | ◯ |
| 104 | | | | | | | | |
| Example | ⊚ | ⊚ | ◯ | ◯ | ◯ | ◯ | ◯ | ◯ |
| 105 | | | | | | | | |
| Example | ⊚ | ⊚ | ◯ | ◯ | ◯ | ◯ | ◯ | ◯ |
| 106 | | | | | | | | |
| Example | ⊚ | ⊚ | ◯ | ◯ | ◯ | ◯ | ◯ | ◯ |
| 107 | | | | | | | | |
| Example | ⊚ | ⊚ | ◯ | ◯ | ◯ | ◯ | ◯ | ◯ |
| 108 | | | | | | | | |
| Example | ⊚ | ⊚ | ◯ | ◯ | ◯ | ◯ | ◯ | ◯ |
| 109 | | | | | | | | |
| Example | ⊚ | ⊚ | ◯ | ◯ | ◯ | ◯ | ◯ | ◯ |
| 110 | | | | | | | | |
| Example | ⊚ | ⊚ | ◯ | ◯ | ◯ | ◯ | ◯ | ◯ |
| 111 | | | | | | | | |
| Example | ⊚ | ⊚ | ◯ | ◯ | ◯ | ◯ | ◯ | ◯ |
| 112 | | | | | | | | |
| Example | ⊚ | ⊚ | ◯ | ◯ | ◯ | ◯ | ◯ | ◯ |
| 113 | | | | | | | | |
| Example | ⊚ | ⊚ | ◯ | ◯ | ◯ | ◯ | ◯ | ◯ |
| 114 | | | | | | | | |
| Example | ⊚ | ⊚ | ◯ | ◯ | ◯ | ◯ | ◯ | ◯ |
| 115 | | | | | | | | |
| Example | ⊚ | ⊚ | ◯ | ◯ | ◯ | ◯ | ◯ | ◯ |
| 116 | | | | | | | | |
| Example | ⊚ | ⊚ | ◯ | ◯ | ◯ | ◯ | ◯ | ◯ |
| 117 | | | | | | | | |
| Example | ⊚ | ⊚ | ◯ | ◯ | ◯ | ◯ | ◯ | ◯ |
| 118 | | | | | | | | |
| Example | ⊚ | ⊚ | ◯ | ◯ | ◯ | ◯ | ◯ | ◯ |
| 119 | | | | | | | | |
| Example | ⊚ | ⊚ | ◯ | ◯ | ◯ | ◯ | ◯ | ◯ |
| 120 | | | | | | | | |
| Example | ⊚ | ⊚ | ◯ | ◯ | ◯ | ◯ | ◯ | ◯ |
| 121 | | | | | | | | |
| Example | ⊚ | ⊚ | ◯ | ◯ | ◯ | ◯ | ◯ | ◯ |
| 122 | | | | | | | | |
| Example | ⊚ | ⊚ | ◯ | ◯ | ◯ | ◯ | ◯ | ◯ |
| 123 | | | | | | | | |
| Example | ⊚ | ⊚ | ◯ | ◯ | ◯ | ◯ | ◯ | ◯ |
| 124 | | | | | | | | |
| Example | ⊚ | ⊚ | ◯ | ◯ | ◯ | ◯ | ◯ | ◯ |
| 125 | | | | | | | | |
| Example | ⊚ | ⊚ | ◯ | ◯ | ◯ | ◯ | ◯ | ◯ |
| 126 | | | | | | | | |
| Example | ⊚ | ⊚ | ◯ | ◯ | ◯ | ◯ | ◯ | ◯ |
| 127 | | | | | | | | |
| Example | ⊚ | ⊚ | ◯ | ◯ | ◯ | ◯ | ◯ | ◯ |
| 128 | | | | | | | | |
| Example | ⊚ | ⊚ | ◯ | ◯ | ◯ | ◯ | ◯ | ◯ |
| 129 | | | | | | | | |
| Example | ⊚ | ⊚ | ◯ | ◯ | ◯ | ◯ | ◯ | ◯ |
| 130 | | | | | | | | |
| Example | ⊚ | ⊚ | ◯ | ◯ | ◯ | ◯ | ◯ | ◯ |
| 131 | | | | | | | | |
| Example | ⊚ | ⊚ | ◯ | ◯ | ◯ | ◯ | ◯ | ◯ |
| 132 | | | | | | | | |
| Example | ⊚ | ⊚ | ◯ | ◯ | ◯ | ◯ | ◯ | ◯ |
| 133 | | | | | | | | |
| Example | ⊚ | ⊚ | ◯ | ◯ | ◯ | ◯ | ◯ | ◯ |
| 134 | | | | | | | | |
| Example | ⊚ | ⊚ | ◯ | ◯ | ◯ | ◯ | ◯ | ◯ |
| 135 | | | | | | | | |
| Example | ⊚ | ⊚ | ◯ | ◯ | ◯ | ◯ | ◯ | ◯ |
| 136 | | | | | | | | |
| Example | ⊚ | ⊚ | ◯ | ◯ | ◯ | ◯ | ◯ | ◯ |
| 137 | | | | | | | | |
| Example | ⊚ | ⊚ | ◯ | ◯ | ◯ | ◯ | ◯ | ◯ |
| 138 | | | | | | | | |

TABLE 14

| | | Film | Transmittance | | | | | |
|---|---|---|---|---|---|---|---|---|
| | | retention | (low | | Chemical | Heat | | Operation |
| | Sensitivity | rate | transmittance) | Adhesion | resistance | resistance | Hygroscopicity | reliability |
| Example | ◯ | ◯ | ◯ | ◯ | ◯ | ◯ | ◯ | ◯ |
| 139 | | | | | | | | |
| Example | ◯ | ⊚ | ⊚ | ◯ | ◯ | ◯ | ◯ | ◯ |
| 140 | | | | | | | | |
| Example | Δ | Δ | Δ | ◯ | ◯ | ◯ | ◯ | ◯ |
| 141 | | | | | | | | |
| Example | Δ | ⊚ | ⊚ | ◯ | ◯ | ◯ | ◯ | Δ |
| 142 | | | | | | | | |
| Example | ⊚ | ◯ | ◯ | ◯ | ◯ | ◯ | ◯ | ◯ |
| 143 | | | | | | | | |
| Example | ⊚ | ◯ | ◯ | ◯ | ◯ | ◯ | ◯ | ◯ |
| 144 | | | | | | | | |
| Example | ⊚ | ◯ | ◯ | ◯ | ◯ | ◯ | ◯ | ◯ |
| 145 | | | | | | | | |
| Example | ⊚ | ◯ | ◯ | ◯ | ◯ | ◯ | ◯ | ◯ |
| 146 | | | | | | | | |
| Example | ⊚ | ◯ | ◯ | ◯ | ◯ | ◯ | ◯ | ◯ |
| 147 | | | | | | | | |
| Example | ⊚ | ◯ | ◯ | ◯ | ◯ | ◯ | ◯ | ◯ |
| 148 | | | | | | | | |
| Example | ◯ | ◯ | ◯ | ◯ | ◯ | ◯ | ◯ | ◯ |
| 149 | | | | | | | | |
| Example | ◯ | ◯ | ◯ | ◯ | ◯ | ◯ | ◯ | ◯ |
| 150 | | | | | | | | |
| Example | ⊚ | ⊚ | ⊚ | ◯ | ◯ | ◯ | ◯ | ◯ |
| 151 | | | | | | | | |
| Example | ◯ | ⊚ | ⊚ | ◯ | ◯ | ◯ | ◯ | ◯ |
| 152 | | | | | | | | |
| Example | Δ | ⊚ | ⊚ | ◯ | ◯ | ◯ | ◯ | ◯ |
| 153 | | | | | | | | |
| Example | Δ | Δ | Δ | ◯ | ◯ | ◯ | ◯ | ◯ |
| 154 | | | | | | | | |

TABLE 15

| | | Film | Transmittance | | | | | |
|---|---|---|---|---|---|---|---|---|
| | | retention | (low | | Chemical | Heat | | Operation |
| | Sensitivity | rate | transmittance) | Adhesion | resistance | resistance | Hygroscopicity | reliability |
| Example | ◯ | ◯ | Δ | ◯ | ◯ | ◯ | ◯ | ◯ |
| 155 | | | | | | | | |
| Example | ◯ | ◯ | Δ | ◯ | ◯ | ◯ | ◯ | ◯ |
| 156 | | | | | | | | |
| Example | ◯ | ◯ | Δ | ◯ | ◯ | ◯ | ◯ | ◯ |
| 157 | | | | | | | | |
| Example | ◯ | ◯ | Δ | ◯ | ◯ | ◯ | ◯ | ◯ |
| 158 | | | | | | | | |
| Comparative | Δ | ◯ | ◯ | Δ | Δ | Δ | Δ | X |
| Example 7 | | | | | | | | |
| Comparative | Δ | ◯ | ⊚ | Δ | Δ | Δ | Δ | X |
| Example 8 | | | | | | | | |
| Comparative | Δ | ◯ | ⊚ | Δ | Δ | Δ | Δ | X |
| Example 9 | | | | | | | | |
| Comparative | Δ | ◯ | ◯ | Δ | Δ | Δ | Δ | X |
| Example | | | | | | | | |
| 10 | | | | | | | | |
| Comparative | Δ | ◯ | ⊚ | Δ | Δ | Δ | Δ | X |
| Example | | | | | | | | |
| 11 | | | | | | | | |
| Comparative | Δ | ◯ | ⊚ | Δ | Δ | Δ | Δ | Δ |
| Example | | | | | | | | |
| 12 | | | | | | | | |
| Comparative | Δ | ◯ | Δ | Δ | Δ | Δ | Δ | X |
| Example | | | | | | | | |
| 13 | | | | | | | | |
| Comparative | Δ | ◯ | ◯ | Δ | Δ | Δ | Δ | X |
| Example | | | | | | | | |
| 14 | | | | | | | | |
| Comparative | Δ | ◯ | ◯ | Δ | Δ | Δ | Δ | X |
| Example | | | | | | | | |
| 15 | | | | | | | | |
| Comparative | Δ | ◯ | Δ | Δ | Δ | Δ | Δ | X |
| Example | | | | | | | | |
| 16 | | | | | | | | |
| Comparative | Δ | ◯ | ◯ | Δ | Δ | Δ | Δ | X |
| Example | | | | | | | | |
| 17 | | | | | | | | |
| Comparative | Δ | ◯ | ◯ | Δ | Δ | Δ | Δ | Δ |
| Example | | | | | | | | |
| 18 | | | | | | | | |
| Example | Δ | Δ | ◯ | ◯ | ◯ | ◯ | ◯ | ◯ |
| 159 | | | | | | | | |
| Example | ⊚ | ◯ | ◯ | ◯ | Δ | ◯ | Δ | Δ |
| 160 | | | | | | | | |
| Example | ◯ | Δ | ⊚ | ◯ | ◯ | ◯ | ◯ | ◯ |
| 161 | | | | | | | | |

Referring to Tables 11 to 15 above, it was confirmed that, as at least any one of the alkali-soluble resin and the photoactive compound had an absorption maximum at a wavelength of 400 to 550 nm as measured by UV-Vis spectroscopy, all the Examples exhibited excellent effects in terms of an appropriate level of sensitivity, film retention rate, adhesion of the cured film to the substrate, chemical resistance, heat resistance, low hygroscopicity, and device reliability compared to the Comparative Examples. As a result of comparing Examples 139 to 142, it was confirmed that, as the degree of sulfonic acid esterification of the photoactive compound was adjusted to 1.2 to 3.0%, the sensitivity, film retention rate, low transmittance, and device operation reliability were all improved.

As a result of comparing Examples 149 to 154, it was confirmed that, as the content of the photoactive compound was adjusted to 5 to 40 parts by weight based on 100 parts by weight of the alkali-soluble resin, the performances in terms of sensitivity, film retention rate, and low transmittance were all improved. In addition, as a result of Examples 149 to 152, it was confirmed that, as the content of the photoactive compound was adjusted to more than 10 and less than 40 parts by weight, specifically 20 to 35 parts by weight, based on 100 parts by weight of the alkali-soluble resin, the sensitivity performance was further improved.

Although the preferred embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

1. A photosensitive resin composition comprising:
an alkali-soluble resin; and
a photoactive compound,
wherein at least any one of the alkali-soluble resin and the photoactive compound has an absorption maximum at a wavelength of 400 to 550 nm as measured by UV-Vis spectroscopy.

2. The photosensitive resin composition of claim 1, wherein at least any one of the alkali-soluble resin and the photoactive compound comprises any one or more of structures represented by Formulas 1, 2-1 to 2-3, and 3 to 7 below: 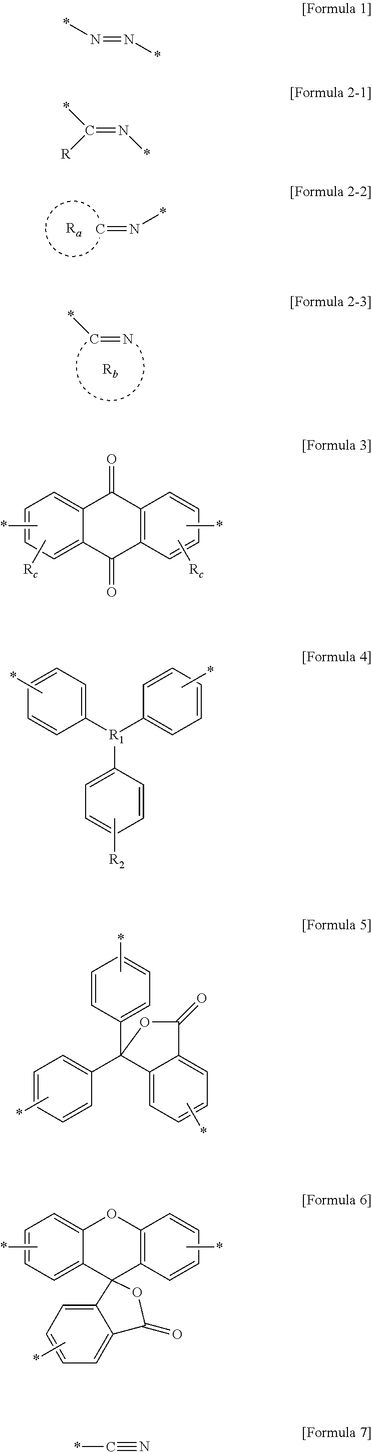
wherein R in Formula 2-1 above is hydrogen or a substituted or unsubstituted organic group;
Rₐ and R_{b} in Formulas 2-2 and 2-3 above are each independently a substituted or unsubstituted pentagonal ring or a substituted or unsubstituted hexagonal ring;
R_{c} in Formula 3 above are each independently a hydrogen atom or a substituted or unsubstituted hydrocarbon group having one or more carbon atoms; and
R₁ in Formula 4 above comprises a trivalent organic group or a nitrogen atom, and R₂ are each independently a hydrogen atom, a hydroxyl group, a sulfonic acid ester group, or a substituted or unsubstituted hydrocarbon group having one or more carbon atoms.

3. The photosensitive resin composition of claim 1, wherein the alkali-soluble resin comprises a structure derived from any one of compounds represented by Formulas 1a to 1j below: 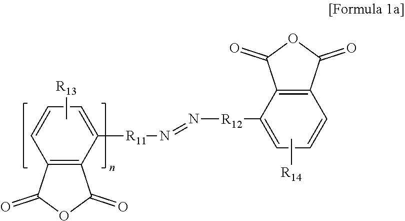
in Formula 1a above,
R₁₁ and R₁₂ each independently comprise a direct bond, a hydrogen atom, or a divalent organic group, wherein, when any one of R₁₁ and R₁₂ is a hydrogen atom, the other is a direct bond or a divalent organic group;
n is 0 or 1; and
R₁₃ and R₁₄ are each independently a hydrogen atom, a hydroxyl group, a substituted or unsubstituted alkyl group having 1 or more carbon atoms, or a substituted or unsubstituted aryl group having 6 or more carbon atoms; 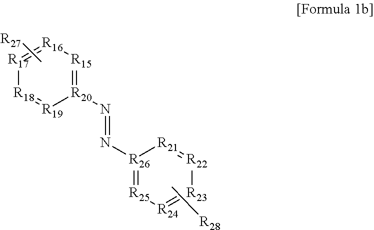
in Formula 1b above,
R₁₅ to R₂₆ are each independently carbon or a heteroatom; and
R₂₇ and R₂₈ are each independently a mono- to penta-substituted substituent in the ring, wherein the substituents each independently comprise a hydrogen atom, a nitro group, a hydroxyl group, or an amine group, and at least any one of the substituents is an amine group; 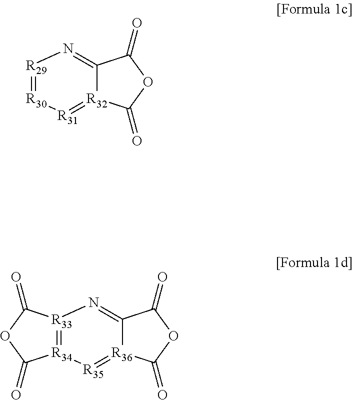
in Formulas 1c and 1d above,
R₂₉ to R₃₆ are each independently carbon or a heteroatom; 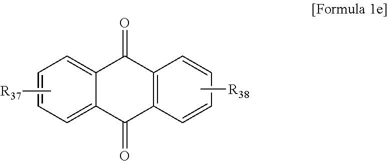
in Formula 1e above,
R₃₇ and R₃₈ are each independently a mono- to tetra-substituted substituent, wherein the substituents are each independently a hydrogen atom, an amine group, or an acid anhydride group, and at least any one of the substituents is an amine group or an acid anhydride group, wherein the acid anhydride group is formed as substituents bond to each other when each of R₃₇ and R₃₈ is poly-substituted; 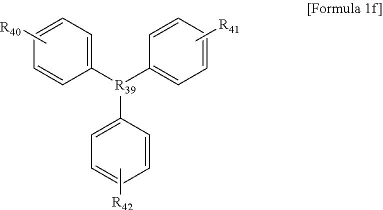
in Formula 1f above,
R₃₉ is a trivalent organic group or a nitrogen atom, and
R₄₀ to R₄₂ are each independently a mono- to penta-substituted substituent which is a hydrogen atom or an amine group, wherein at least any one of R₄₀ to R₄₂ is an amine group; 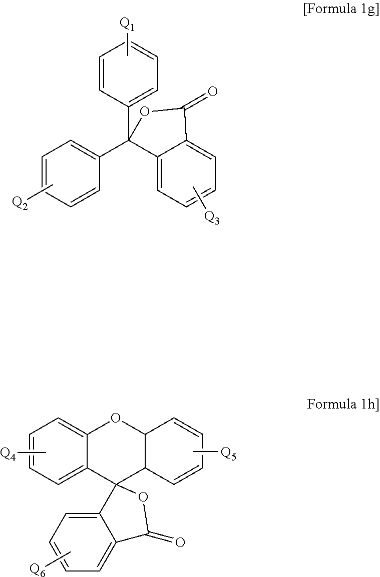
in Formulas 1g and 1h above,
Q₁ to Q₆ are each independently a mono- or poly-substituted substituent which is a hydrogen atom, an amine group, or an acid anhydride group,
wherein at least any one of Q₁ to Q₃ is an amine group or an acid anhydride group, wherein the acid anhydride group is formed as substituents bond to each other when any one or more of Q₁ to Q₃ are poly-substituted, and
wherein at least any one of Q₄ to Q₆ is an amine group or an acid anhydride group, wherein the acid anhydride group is formed as substituents to each other when any one or more of Q₄ to Q₆ are poly-substituted; 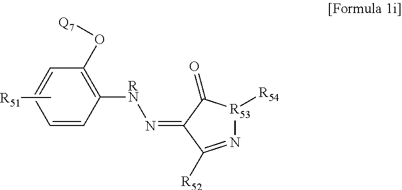
in Formula 1i above,
Q₇ comprises a hydrogen atom, a substituted or unsubstituted alkyl group having 1 or more carbon atoms, a substituted or unsubstituted aryl group having 6 or more carbon atoms, an amine group, or an acid anhydride group, wherein Q₇ comprises at least one amine group or at least one acid anhydride group;
R₅₁, R₅₂, and R₅₄ are each independently a hydrogen atom, a nitro group, a hydroxyl group, a substituted or unsubstituted alkyl group having one or more carbon atoms, or a substituted or unsubstituted aryl group having 6 or more carbon atoms;
R₅₃ is a nitrogen atom; and
R bonded to N is a hydrogen atom or a substituted or unsubstituted organic group; 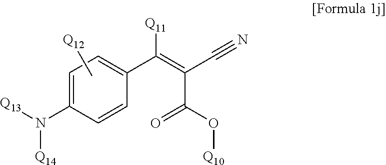
in Formula 1j above,
Q₁₀ to Q₁₂ are each independently a hydrogen atom, a hydroxyl group, a substituted or unsubstituted alkyl group having one or more carbon atoms, or a substituted or unsubstituted aryl group having 6 or more carbon atoms, and
Q₁₃ and Q₁₄ each independently comprise a hydrogen atom, at least one amine group, or at least one acid anhydride group.

4. The photosensitive resin composition of claim 1, wherein the alkali-soluble resin comprises any one selected from the group consisting of polyamic acid, polyamic ester, and polyimide.

5. The photosensitive resin composition of claim 4, wherein a degree of imidization of the polyimide is 50% or more.

6. The photosensitive resin composition of claim 3, wherein the alkali-soluble resin comprises a structure derived from any one of the compounds represented by Formulas 1a to 1j in an amount of 5 mol % or more based on the total moles of the alkali-soluble resin.

7. The photosensitive resin composition of claim 1, wherein the photoactive compound comprises a sulfonic acid-esterified quinone diazide compound.

8. The photosensitive resin composition of claim 7, wherein the sulfonic acid-esterified quinone diazide compound comprises a phenolic compound as a ballast.

9. The photosensitive resin composition of claim 8, wherein the phenolic compound comprises any one or more of compounds represented by Formulas 2a to 2j below: 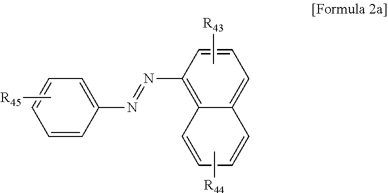
in Formula 2a above,
R₄₃ to R₄₅ are each independently a mono- or poly-substituted substituent, wherein the substituents are each independently a hydrogen atom, a nitro group, or a hydroxyl group, and
at least any one of the substituents is a hydroxyl group; 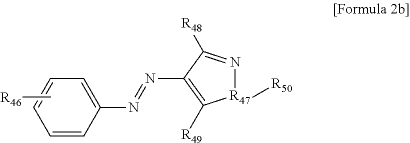
in Formula 2b above,
R₄₆ is a mono- to penta-substituted substituent which are each independently a hydrogen atom, a nitro group, or a hydroxyl group, wherein at least any one of R₄₆ comprises a hydroxyl group;
R₄₇ is a nitrogen atom; and
R₄₈ to R₅₀ are each independently a hydrogen atom, a hydroxyl group, a nitro group, a substituted or unsubstituted alkyl group having one or more carbon atoms, or a substituted or unsubstituted aryl group having 6 or more carbon atoms; 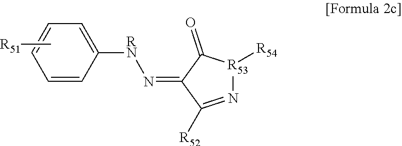
in Formula 2c above,
R₅₁ is a mono- to penta-substituted substituent which are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of R₅₁ is a hydroxyl group;
R₅₂ and R₅₄ are each independently a hydrogen atom, a nitro group, a hydroxyl group, a substituted or unsubstituted alkyl group having one or more carbon atoms, or a substituted or unsubstituted aryl group having 6 or more carbon atoms;
R₅₃ is a nitrogen atom; and
R bonded to N is a hydrogen atom or a substituted or unsubstituted organic group; 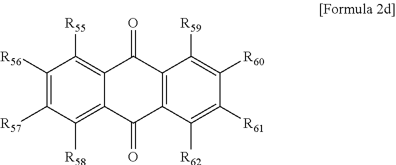
in Formula 2d above,
R₅₅ to R₆₂ are each independently a hydrogen atom, a nitro group, a hydroxyl group, a substituted or unsubstituted alkyl group having one or more carbon atoms, or a substituted or unsubstituted aryl group having 6 or more carbon atoms,
wherein at least any one of R₅₅ to R₆₂ is a hydroxyl group; 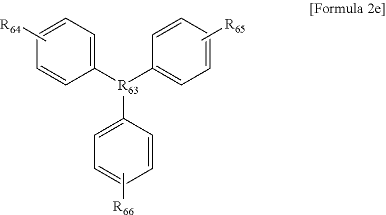
in Formula 2e above,
R₆₃ is a trivalent organic group or a nitrogen atom; and
R₆₄ to R₆₆ are each independently a mono- to penta-substituted substituent which is a hydrogen atom, a nitro group, a hydroxyl group, a substituted or unsubstituted alkyl group having one or more carbon atoms, or a substituted or unsubstituted aryl group having 6 or more carbon atoms, wherein at least any one of R₆₄ to R₆₆ is a hydroxyl group; 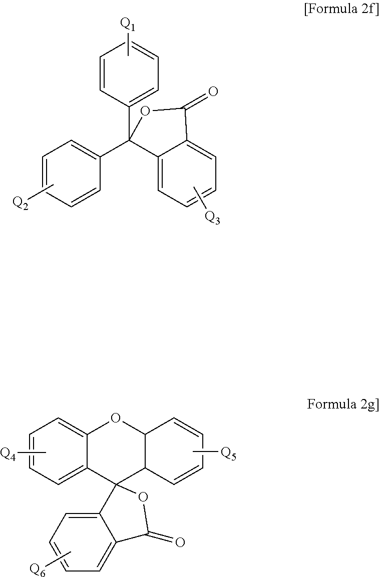
in Formulas 2f and 2g above,
Q₁ to Q₆ are each independently a mono- or poly-substituted substituent, and are each independently a hydrogen atom, a nitro group, a hydroxyl group, a substituted or unsubstituted alkyl group having one or more carbon atoms, or a substituted or unsubstituted aryl group having 6 or more carbon atoms,
at least any one of Q₁ to Q₃ is a hydroxyl group, and at least any one of Q₄ and Q₆ is a hydroxyl group; 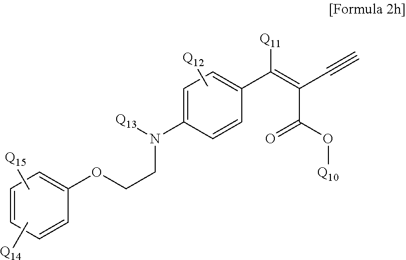
in Formula 2h above,
Q₁₀ to Q₁₂ are each independently a hydrogen atom, a nitro group, a hydroxyl group, a substituted or unsubstituted alkyl group having one or more carbon atoms, or a substituted or unsubstituted aryl group having 6 or more carbon atoms;
Q₁₃ is a hydrogen atom, a substituted or unsubstituted alkyl group having one or more carbon atoms, or a substituted or unsubstituted aryl group having 6 or more carbon atoms; and
Q₁₄ and Q₁₅ are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of Q₁₄ and Q₁₅ is a hydroxyl group; 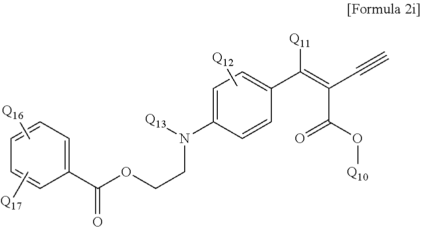
in Formula 2i above,
Q₁₀ to Q₁₂ are each independently a hydrogen atom, a nitro group, a hydroxyl group, a substituted or unsubstituted alkyl group having one or more carbon atoms, or a substituted or unsubstituted aryl group having 6 or more carbon atoms;
Q₁₃ is a hydrogen atom, a substituted or unsubstituted alkyl group having one or more carbon atoms, or a substituted or unsubstituted aryl group having 6 or more carbon atoms; and
Q₁₆ and Q₁₇ are each independently a hydrogen atom, a nitro group, a hydroxyl group, a substituted or unsubstituted alkyl group having one or more carbon atoms, or a substituted or unsubstituted aryl group having 6 or more carbon atoms, wherein at least any one of Q₁₆ and Q₁₇ is a hydroxyl group; 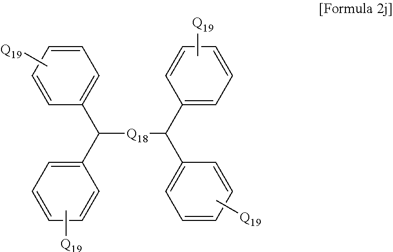
in Formula 2j above,
Q₁₈ is a divalent linking group comprising at least one aromatic ring, and
Q₁₉ are each independently a mono- to penta-substituent in the benzene ring, wherein at least any one of the mono- to penta-substituted substituents is a hydroxyl group.

10. The photosensitive resin composition of claim 7, wherein the content of the sulfonic acid-esterified quinone diazide compound is 5 to 40 parts by weight based on 100 parts by weight of the alkali-soluble resin.

11. The photosensitive resin composition of claim 1, further comprising a solvent.

12. The photosensitive resin composition of claim 1, further comprising at least any one of a crosslinking agent, a thermal acid generator, and a UV absorber.

13. The photosensitive resin composition of claim 7, wherein the degree of sulfonic acid esterification of the sulfonic acid-esterified quinone diazide compound is 1.0 to 3.3% as measured according to an ultra-performance liquid chromatography (UPLC) analysis method.

14. An insulating film comprising a cured product of the photosensitive resin composition according to claim 1.

15. A display device comprising the insulating film according to claim 14.
